(19) United States
(12) Patent Application Publication
(10) Pub. No.: US 2022/0358256 A1
(43) Pub. Date: Nov. 10, 2022

(54) SYSTEMS AND METHODS FOR REMOTE MANIPULATION OF MULTI-DIMENSIONAL MODELS

(71) Applicant: Intrface Solutions LLC, Denver, CO (US)

(72) Inventors: Matthew Michael Segler, Denver, CO (US); Alexander W. Baer, Denver, CO (US); Saiharshith Kilaru, Denver, CO (US); Sean Patrick Cody, Denver, CO (US); Jake Matthew DePiero, Denver, CO (US)

(73) Assignee: Intrface Solutions LLC, Denver, CO (US)

(21) Appl. No.: 17/634,216

(22) PCT Filed: Oct. 25, 2021
(86) PCT No.: PCT/US2021/056514

§ 371 Date: Feb. 9, 2022

Related U.S. Application Data
(60) Provisional application No. 63/204,853, filed on Oct. 29, 2020.

(51) Int. Cl. G06F 30/12; G06F 3/04886; G06F 3/04815; G06F 3/04845

(52) U.S. Cl. CPC G06F 30/12; G06F 3/04886; G06F 3/04815; G06F 3/04845; G06F 2203/04806

(57) ABSTRACT

The present disclosure relates to enabling a user device to manipulate a multi-dimensional model maintained by a computing device. An application on the user device can receive requests from the user to manipulate the model via programmable hot keys, a shortcut keyboard, or voice commands. The user device can send these requests to the computing device, which provides the requests to a CAD program executed by the computing device to manipulate the model. By executing the application on the user device and the driver on the computing device, the present disclosure can enable the user device to manipulate models on the computing device, which is a more efficient and intuitive technique for the user.

### RELATED APPLICATIONS

This application is a U.S. National Phase Application under 35 U.S.C. § 371 of International Application No. PCT/US2021/056514, filed on Oct. 25, 2021, titled “SYSTEMS AND METHODS FOR REMOTE MANIPULATION OF MULTI-DIMENSIONAL MODELS,” which in turn claims the benefit of and priority to U.S. Patent Provisional Patent Application No. 63/204,853 filed on Oct. 29, 2020, titled “COMPUTER AIDED DESIGN MOBILE APPLICATION OFFERING 6 DEGREE OF FREEDOM MODEL MANIPULATION AND SHORTCUTS,” the contents of all of which are incorporated herein.

### FIELD OF THE DISCLOSURE

The present application generally relates to manipulating multi-dimensional models.

### BACKGROUND OF THE DISCLOSURE

Engineers, architects, and creatives alike use Computer Aided Design (CAD), such as 3D CAD to model 3D objects in virtual space. Such models can be a blueprint for the overall design used in manufacturing. However, viewing and controlling the models is difficult.

### BRIEF SUMMARY OF THE DISCLOSURE

The present disclosure described herein relates to CAD, specifically to improving the efficiency of 3D CAD users through increased user input bandwidth. User input bandwidth can be defined by the rate at which a user inputs commands into the computer or enters information into and interacts with the 3D CAD program. CAD users often struggle with the ability to quickly input an idea into a 3D CAD model.

Quantitatively this speed and/or efficiency that results from increased user bandwidth is defined by the speed at which a 3D CAD model can be completed. Data that can be entered into the CAD program include sketches, dimensions and surfaces that will make up the final model. This data is entered using various commands such as sketch, extrude, cut, mate (connect two parts in an assembly), and many more that are generally found in a command window within the CAD program. In a typical workflow setup, the user will select these commands with his or her computer mouse. Interactions with the model using the mouse include the movement of an object in 3D space by panning or translating the model, zooming in/out on the model, and rotating the model. A typical CAD user will exclusively use a computer mouse and occasionally a keyboard to navigate the model within 3D space, select geometry, and input commands. This approach causes the user to mostly use their dominant hand while their non-dominant hand remains idle, which limits how quickly the user can work.

The present disclosure provides a mobile device as an additional input into the program to enable for faster creation of the 3D model. The present disclosure is directed to providing at least a mobile application to be used on user device and a driver to be used on a computer. Providing users with a mobile application to be used in conjunction with a traditional mouse can allow users to work faster. Providing a mobile application executing on a mobile device can improve CAD user input bandwidth and thus user efficiency, which can improve the way 3D design in CAD is performed. The implementations described herein can decrease the learning curve, which can be defined as the amount of time the user needs to understand how to use the implementations described herein. The mobile implementation is more intuitive to the user.

Features in this application may include the ability to navigate the model with six degrees of freedom (zoom, pan, and rotate), programmable hotkeys (commands), a shortcut keyboard, voice command, and an ergonomic functional display on the mobile interface. Six degrees of freedom can be defined as the ability to zoom in and out on the 3D model, pan the 3D model, and rotate the 3D model. Hotkeys can be commands that are used in the 3D CAD software that are programmable buttons on the mobile interface. A shortcut keyboard can be an on-screen alphabetic and/or numerical keyboard that will allow the user to enter various alphanumeric inputs into the CAD program including, but not limited to, dimensions, global variables, etc. Voice command can be defined as the ability of the software to recognize a user's vocal input and cause the 3D CAD program to perform the stated action.

The mobile application can improve the efficiency of CAD users through offering additional user input bandwidth by relying on an application for mobile devices (such as smartphones, tablets, touchpads, or personal music devices, among others). The mobile application can allow the user to perform model manipulation, voice commands, or select buttons in the application that correspond to commands in the CAD program. This improved bandwidth of the user can increase user efficiency, which can be defined by a speed of designing a part or assembly.

The present disclosure relates to a method for a user device to manipulate a multi-dimensional model maintained by a computing device. The method can include displaying, by one or more processors of the user device, on a screen of the user device, a manipulation area for controlling display of the multi-dimensional model maintained by the computing device. The method can include receiving, by the one or more processors, from a gesture handler of the user device, an identification of an input received by the screen of the user device. The method can include generating, by the one or more processors, based on the identification, an instruction for manipulating a digital object in a digital space. The method can include transmitting, by the one or more processors, the instruction to a driver of the computing device to manipulate display of the digital object in the digital space maintained by the computing device.

In some implementations, generating the instruction comprises generating, by the one or more processors, based on the identification, the instruction comprising a rotation identifier and coordinates for rotating the digital object in the digital space.

In some implementations, generating the instruction comprises generating, by the one or more processors, based on the identification, the instruction comprising a rotation identifier and coordinates for rotating the digital space.

In some implementations, generating the instruction comprises generating, by the one or more processors, based on the identification, the instruction comprising a zoom identifier and a scaling factor for zooming in the digital space.

In some implementations, the identification is a first identification and the input is a first input. In some implementations, generating the instruction comprises receiving, by the one or more processors, from the gesture handler of the user device, a second identification of a second input received by the user device. In some implementations, generating the instruction comprise generating, by the one or more processors, based on receiving the first identification and the second identification within a predetermined amount of time, the instruction for manipulating the digital object in the digital space.

In some implementations, generating the instruction comprises generating, by the one or more processors, based on the identification, the instruction comprising a pan identifier and a direction to pan in the digital space.

In some implementations, the method includes maintaining, by the one or more processors, a predetermined instruction for manipulating the digital object in the digital space. In some implementations, the method includes displaying, on the screen of the user device, a button corresponding to the predetermined instruction. In some implementations, the method includes receiving, by the one or more processors, from the gesture handler of the user device, a selection of the button on the user device. In some implementations, the method includes transmitting, by the one or more processors, the predetermined instruction to the driver of the computing device to manipulate display of the digital object in the digital space maintained by the computing device.

In some implementations, the method includes displaying, by the one or more processors, on the screen of the user device, a request to configure the button. In some implementations, the method includes receiving, by the one or more processors, subsequent to the request, alphanumeric input corresponding to the button. In some implementations, the method includes updating, by the one or more processors, based on the alphanumeric input, the predetermined instruction associated with the button for manipulating the digital object in the digital space.

In some implementations, receiving the identification of the input comprises receiving, by the one or more processors, from an audio handler of the user device, the identification of the input received by a microphone of the user device.

In some implementations, generating the instruction comprises identifying, by the one or more processors, a predetermined instruction corresponding to the identification. In some implementations, generating the instruction comprises generating, by the one or more processors, based on the predetermined instruction, the instruction for manipulating the digital object in the digital space.

In some implementations, transmitting the instruction comprises transmitting, by the one or more processors, a request to the computing device to connect with the computing device via Bluetooth or USB. In some implementations, transmitting the instruction comprises receiving, by the one or more processors, a response from the computing device to establish a connection with the computing device via Bluetooth or USB. In some implementations, transmitting the instruction comprises transmitting, by the one or more processors, via the connection, the instruction to the driver of the computing device to manipulate display of the digital object of the digital space maintained by the computing device.

In some implementations, generating the instruction comprises receiving, by the one or more processors, from the computing device, a request for alphanumeric input. In some implementations, generating the instruction comprises displaying, by the one or more processors, a keyboard responsive to the request.

In another aspect, the present disclosure relates to a method for a computing device to enable a user device to manipulate a multi-dimensional model maintained by an application of the computing device. The method can include receiving, by one or more processors of the computing device, from the user device, an instruction to manipulate display of the multi-dimensional model maintained by the application of the computing device. The method can include generating, by the one or more processors, based on the instruction, a command for manipulating a digital object in a digital space. The method can include providing, by the one or more processors, the command to the application to manipulate the digital object in the digital space.

In some implementations, generating the command comprises identifying, by the one or more processors, from the instruction, a rotation identifier and coordinates on a screen of the user device. In some implementations, generating the command comprises identifying, by the one or more processors, a center of rotation for the digital object in the digital space. In some implementations, generating the command comprises generating, by the one or more processors, based on the coordinates on the screen of the user device and the center of rotation, the command comprising a rotation request for rotating the digital object in the digital space.

In some implementations, identifying the center of rotation comprises identifying, by the one or more processors, pixel identifiers at each corner of the digital space displayed on a screen of the computing device. In some implementations, identifying the center of rotation comprises identifying, by the one or more processors, based on the pixel identifiers, a first point having three dimensional coordinates at a center of the digital space. In some implementations, identifying the center of rotation comprises generating, by the one or more processors, a second point having three dimensional coordinates, the second point forming a vector that is normal to a z-axis of the digital space displayed on the screen of the computing device. In some implementations, identifying the center of rotation comprises assigning, by the one or more processors, based on the first point and the second point, one or more bounding boxes to the digital object in the digital space. In some implementations, identifying the center of rotation comprises identifying, by the one or more processors, one or more intersections between the one or more bounding boxes and the vector. In some implementations, identifying the center of rotation comprises identifying, by the one or more processors, based on the one or more intersections, the center of rotation for the digital object in the digital space.

In some implementations, generating the command comprises identifying, by the one or more processors, from the instruction, a rotation identifier and coordinates on a screen of the user device. In some implementations, generating the command comprises generating, by the one or more processors, coordinates of the digital space based on the coordinates on the screen of the user device. In some implementations, generating the command comprises generating, by the one or more processors, based on the instruction, the command comprising a rotation request and the coordinates of the digital space.

In some implementations, generating the command comprises identifying, by the one or more processors, from the instruction, a zoom identifier and scaling factor. In some implementations, generating the command comprises generating, by the one or more processors, based on the instruction, the command comprising a zoom request and the scaling factor for zooming in the digital space.

In some implementations, generating the command comprises identifying, by the one or more processors, from the instruction, a pan identifier and a direction to pan in the digital space. In some implementations, generating the command comprises generating, by the one or more processors, based on the instruction, the command comprising a pan request and the direction to pan in the digital space.

In some implementations, receiving the instruction comprises receiving, by the one or more processors, a request to from the user device to connect via Bluetooth or USB. In some implementations, receiving the instruction comprises transmitting, by the one or more processors, a response to the user device to establish a connection with the user device via Bluetooth or USB. In some implementations, receiving the instruction comprises receiving, by the one or more processors, via the connection, the instruction to manipulate display of the digital object in the digital space maintained by the application of the computing device.

In some implementations, the method comprises identifying, by the one or more processors, a request by the application for alphanumeric input. In some implementations, the method comprises transmitting, by the one or more processors, the request to the user device for the alphanumeric input.

The details of various implementations are set forth in the accompanying drawings and the description below.

### BRIEF DESCRIPTION OF THE FIGURES

The accompanying drawings are not intended to be drawn to scale. Like reference numbers and designations in the various drawings indicate like elements. For purposes of clarity, not every component can be labeled in every drawing. In the drawings:

FIG. 1 is a diagram illustrating an implementation of a user device to manipulate a multi-dimensional model maintained by a computing device;

FIG. 2 is a system diagram illustrating an implementation of the user device to manipulate the multi-dimensional model maintained by the computing device;

FIG. 3A is an implementation of a user interface displayed on the user device to manipulate the multi-dimensional model maintained by the computing device;

FIG. 3B is an implementation of a user interface including a keypad displayed on the user device to manipulate the multi-dimensional model maintained by the computing device;

FIG. 3C is an implementation of a user interface including a menu displayed on the user device to manipulate the multi-dimensional model maintained by the computing device;

FIG. 3D is an implementation of a user interface including hotkey labels displayed on the user device to manipulate the multi-dimensional model maintained by the computing device;

FIG. 3E is an implementation of a user interface including gesture sensitivity displayed on the user device to manipulate the multi-dimensional model maintained by the computing device;

FIG. 4 is a flow diagram of an implementation of a method for the user device to manipulate the multi-dimensional model maintained by the computing device;

FIG. 5 is a flow diagram of an implementation of a method for the user device to maintain a connection with the computing device;

FIG. 6 is a flow diagram of an implementation of a method for using a keyboard on the user device to manipulate the multi-dimensional model maintained by the computing device;

FIG. 7 is a flow diagram of an implementation of a method for the user device to handle user inputs to manipulate the multi-dimensional model maintained by the computing device; and

FIG. 8 is a flow diagram of an implementation of a method for the user device to manipulate the multi-dimensional model maintained by the computing device.

The features and advantages of the present solution will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

Below are detailed descriptions of various concepts related to, and implementations of, techniques, approaches, methods, apparatuses, and systems for a user device to manipulate a multi-dimensional model maintained by a computing device. The various concepts introduced above and discussed in detail below can be implemented in any of numerous ways, as the described concepts are not limited to any particular manner of implementation. Examples of specific implementations and applications are provided primarily for illustrative purposes.

The present disclosure relates to enabling a user device to manipulate a multi-dimensional model maintained by a computing device. For example, a user can use the user device to manipulate CAD models on the computing device. An application on the user device can receive requests from the user to manipulate the model via programmable hot keys, a shortcut keyboard, or voice commands. The user device can receive requests to zoom in and out on the model, pan the model, or rotate the model. The user device can send these user requests to a driver executed by the computing device. The driver receives the requests and interfaces with a CAD program executed by the computing device to manipulate the model in accordance with the request. By executing the application on the user device (e.g., smartphones, tablets, touchpads, etc.) and the driver on the computing device, the present disclosure can enable the user device to manipulate models on the computing device. The user device allows the user to use buttons, keyboards, or voice commands to manipulate models on the computing device, which is a more efficient and intuitive technique for the user to manipulate CAD models.

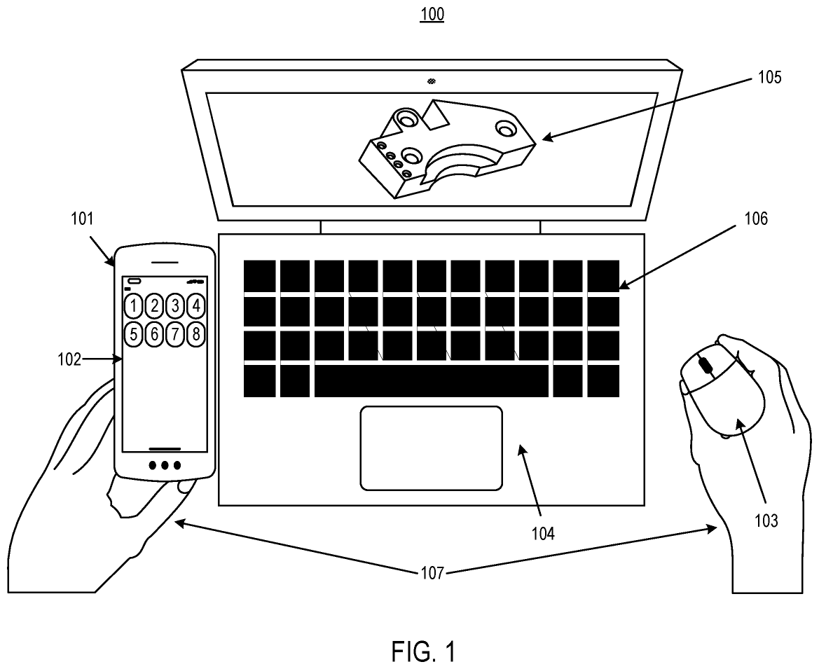

Referring now to FIG. 1, shown is a diagram illustrating an implementation of a user device 101 to manipulate a multi-dimensional model 105 maintained by a computing device 104. The user device 101 can be a mobile phone. The user 107 can use the user device 101 to manipulate the multi-dimensional model 105 (e.g., a model in a CAD package 220 described herein). The user device 101 can include a user interface 102 for with selectable controls to manipulate the multi-dimensional model 105 maintained or displayed by the computing device 104. p The computing device 104 can communicate with the user device 101 to receive inputs from the user 107 to manipulate the multi-dimensional model 105. The computing device 104 can be a computer communicatively coupled to a display and a computer mouse 103. The computing device 104 can be a computer such as a laptop or a desktop. The computing device 104 can include a display for displaying the model 105. The computing device 104 can be communicatively coupled to an input device such as the computer mouse 103, trackpad, or the keyboard 106.

The user 107 can use the computer mouse 103 or the keyboard 106 of the computing device 104 to manipulate the multi-dimensional model 105. In one example, while using the user device 101 to manipulate the multi-dimensional model 105, the user 107 can use the computer mouse 103 or the keyboard 106 of the computing device 104 to manipulate the multi-dimensional model 105.

The present disclosure enables the user 107 to navigate the model with six degrees of freedom with his/her hand by using the user interface 102 while simultaneously working with the traditional mouse 103 and/or the keyboard 106. In contrast, typical implementations involve the user 107 using one hand to use the computer mouse 103 and occasionally typing on the keyboard 106.

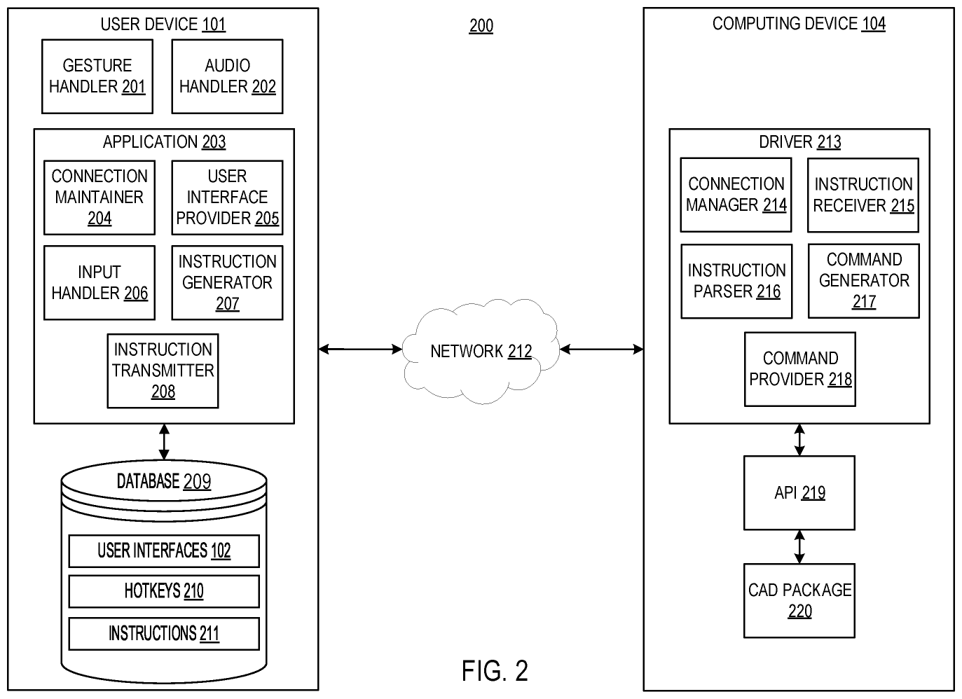

Referring now to FIG. 2, shown is a system 200 diagram illustrating an implementation of the user device 101 to manipulate the multi-dimensional model 105 maintained by the computing device 104. The user device 101 can include a gesture handler 201, an audio handler 202, and an application 203. The application 203 can include a connection maintainer 204, a user interface provider 205, an input handler 206, an instruction generator 207, and an instruction transmitter 208. The application 203 can be coupled to a database 209, which can include user interfaces 102, hotkeys 210, and instructions 211. The system 200 can include a network 212. The computing device 104 can include a driver 213, which can include a connection manager 214, an instruction receiver 215, an instruction parser 216, a command generator 217, and a command provider 218. The driver 213 can use an API 219 to communicate with the CAD package 220.

Still referring to FIG. 2 and in further detail, the user device 101 can be any electronic device such as an iPhone (By APPLE of Cupertino, Calif.), Apple iPad (By APPLE), or a Samsung Galaxy (Samsung Electronics of Suwon-si, South Korea). The user 107 can use the user device 101 with his or her left hand to use the application 203.

The gesture handler 201 of the user device 101 can receive and manage haptic inputs via a touch screen of the user device 101. The gesture handler 201 can detect haptic inputs from the user 107 on the touch screen, and extract data from the haptic inputs to identify the user inputs. For example, the gesture handler 201 can identify that the user 107 dragged their finger across the touch screen.

The gesture handler 201 of the of the user device 101 can translate, process, or convert touches to touch data. The gesture handler 201 is specific to the operating system of the user device 101. The application 203 can process the raw touch data into inputs for sending as instructions 211 to the driver 213 of the computing device 104, which converts the instructions 211 to commands for the CAD package 220. The gesture handler 201 can provide the touch data to the input handler 206. For example, the touch data can indicate that the user 107 dragged their finger across the screen.

The audio handler 202 of the user device 101 can receive and process audio inputs from the user 107. For example, the audio handler 202 can convert speech to text. The audio handler 202 can receive audio inputs from the user 107 via a microphone communicatively coupled to the user device 101, and extract data from the audio inputs to identify what the user 107 is saying. For example, the audio handler 202 can identify that the user 107 said “zoom the model by a scaling factor of 2.”

The application 203 of the user device 101 can enable the user device 101 to manipulate the multi-dimensional model 105 maintained by the computing device 104. The user device 101 can download, install, and execute the application 203. For example, the user device 101 can download the application 203 from the Apple App Store (Apple of Cupertino, Calif.), Google Play store (Alphabet Inc. of Mountain View, Calif.), or any other application store.

The connection maintainer 204 of the application 203 can establish or maintain a connection with the driver 213 of the computing device 104. The connection can be via USB or Bluetooth. Connections via USB can be established via Transport Control Protocol (TCP). In one example, the connection maintainer 204 can establish the connection via the network 212, which can be the internet, Wi-Fi, or Cellular (e.g., 2G, 3G, 4G, and 5G).

The connection maintainer 204 can verify the connection with the computing device 104. In some implementations, connection maintainer 204 can transmit a request to the computing device 104 to connect with the computing device 104 via Bluetooth or USB. The verification can be different depending on the operating system of the user device 101. For example, a user device 101 executing Android can transmit a “heartbeat” message every half second to notify the computing device 104 of the connection. The computing device 104 can respond to the user device 101 with an acknowledgment message responsive to receiving a heartbeat message. In some implementations, connection maintainer 204 can receive, a response from the computing device 104 to establish the connection with the computing device 104 via Bluetooth or USB. If the computing device 104 (e.g., desktop/laptop computer) does not receive a heartbeat, the computing device 104 can return to a mode where it will try to connect to the user device 101. For example, the user interface provider 205 can display a “not connected” message whenever the connection maintainer 204 fails to receive an acknowledgment message within a predetermined amount of time (e.g., two seconds). In another example, the user interface provider 205 can display the “not connected” message when the connection disconnects. In another example, the connection maintainer 204 on a user device 101 executing iOS can establish a USB connection with a TCP channel to send commands. For Bluetooth connections, the user device 101 can verify the connection similarly to that of Android.

The user interface provider 205 of the application 203 can manage display of user interfaces 102 on the screen of the user device 101 for the user 107 to manipulate the multi-dimensional model 105 maintained by the computing device 104. The user interfaces 102 can be optimized for left-hand operation or right-hand operation by the user 107.

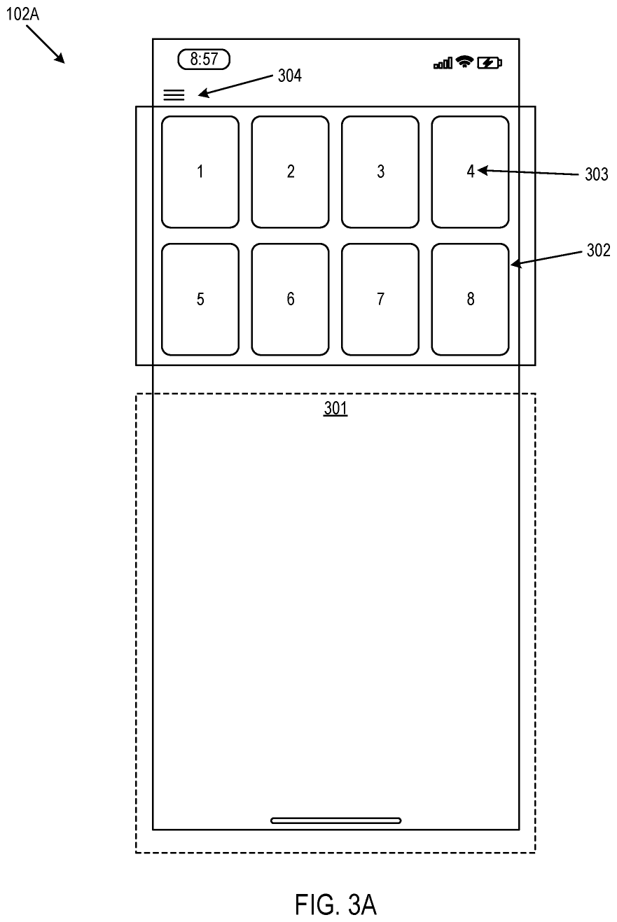

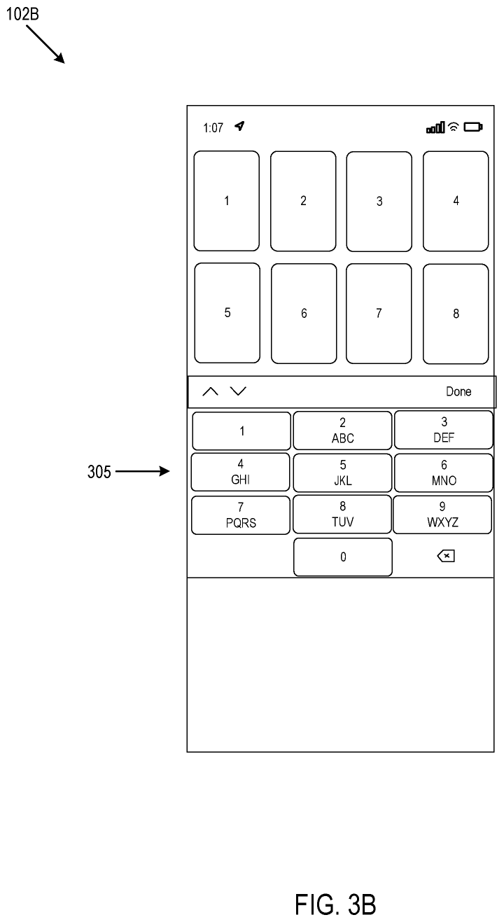

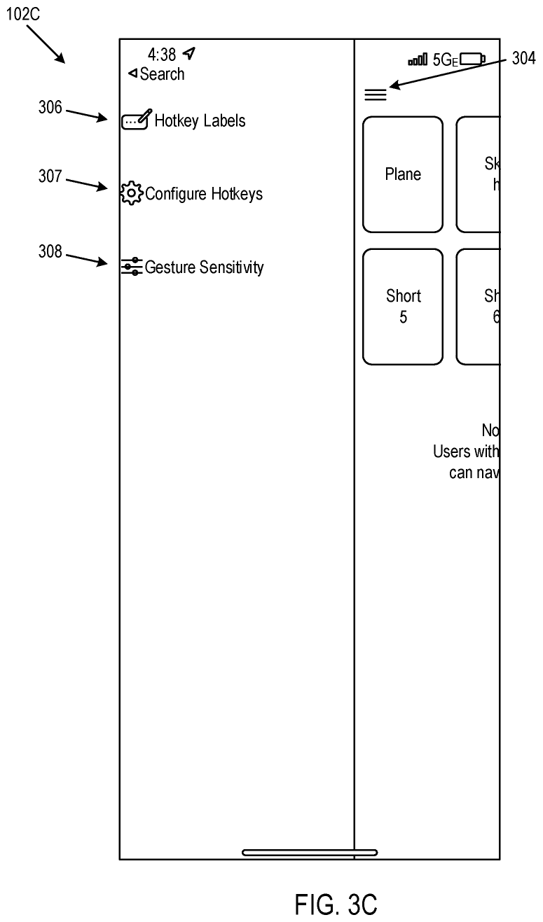

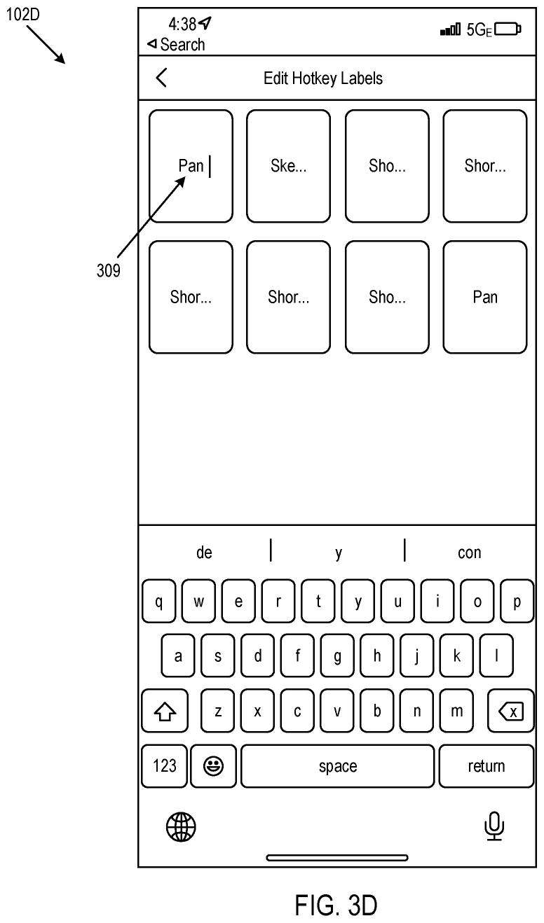

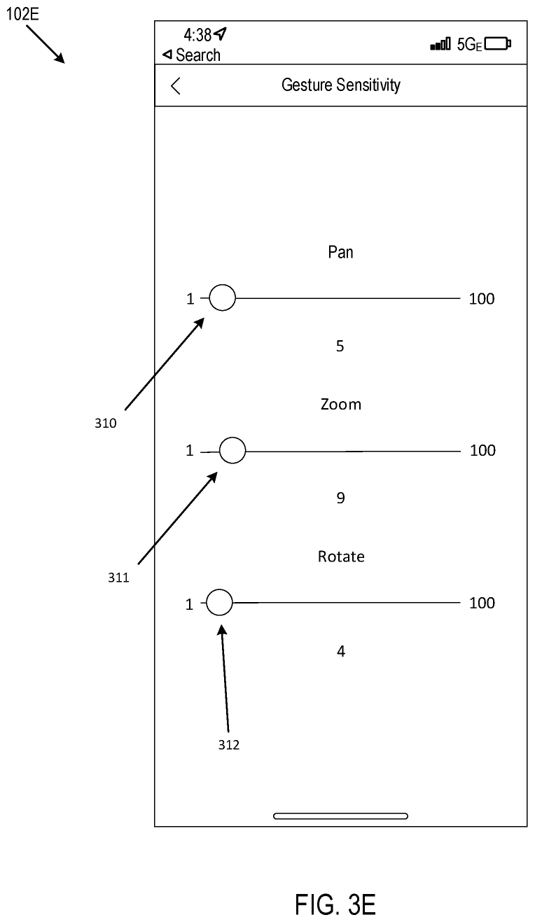

Referring now to FIG. 3A in conjunction with FIG. 2, shown is an implementation of a user interface 102A displayed on the user device 101 to manipulate the multi-dimensional model 105 maintained by the computing device 104. In some implementations, the user interface provider 205 can display, on the screen of the user device 101, a manipulation area 301 for controlling display of the multi-dimensional model 105 maintained by the computing device 104. The manipulation area 301 of the user interface 102A can be the area for the user 107 to provide touches to manipulate the model 105. The gesture handler 201 can handle the touches received from the user 107 in the manipulation area 301.

The user interface 102A can include buttons 302 corresponding to the hotkeys 210. The hotkeys 210 can define functionality that the user 107 can define as specific commands or custom-made commands (macros) into each of the buttons 302. The hotkeys 210 can correspond to any command that is in the CAD package 220 or custom-made commands (macros). For example, the hotkeys 210 can specify keypresses such as “CTRL+ALT+Shift+F20”. Other examples of commands that can be included in the hotkeys 210 include “Extrude”, “Cut”, or “Sketch.” Yet another example of pre-programmed hotkeys 210 including “Enter” or re-centering the model 105 within the CAD package 220. In some implementations, the user interface provider 205 can display, on the screen of the user device 101, a button 302 corresponding to the instructions 211 for controlling the model 105. Another configuration for hotkeys 210 could include having all available hotkeys 210 within the application 203 that would send the instructions 211 to the driver 213, which would then call the specific CAD package 220 via the API 219 corresponding to the selected function in the instructions 211. In some implementations, the database 209 can maintain the instructions 211 corresponding to the hotkeys 210 for manipulating the digital object in the digital space.

The user interface 102A can include labels 303 for each of the buttons 302. The application 203 can receive, via the user interfaces 102, text corresponding to the labels 303 for these buttons 302. The labels 303 can correspond to the name of the function or custom command that the user 107 wishes to program into each specific hotkey 210.

Referring now to FIG. 3B in conjunction with FIG. 2, shown is an implementation of a user interface 102B including a keypad 305 displayed on the user device 101 to manipulate the multi-dimensional model 105 maintained by the computing device 104. They keypad 305 can be a pop-up keypad. While shown is a keypad 305, it is contemplated that the user interface 102 can include a keyboard. The user interface provider 205 can cause the display of the user interface 102B including the keypad 305. In one example, the user interface provider 205 can provide, display, or generate the keypad 305 after a specific button 302 corresponding to the hotkey 210 is selected. In another example, the user interface provider 205 can cause the operating system of the user device 101 to display the keypad 305.

The user interface provider 205 can cause display of the keypad 305 responsive to functions being called within the CAD package 220 of the computing device 104. In some implementations, the connection maintainer 204 can receive, from the computing device 104, a request for alphanumeric input. For example, the application 203 can detect that the CAD package 220 on the computing device 104 can receive inputs via the keypad 305 because the CAD package 220 opened a settings window or the user 107 inputted an extrude command on the computing device 104 and the CAD package 220 requested a dimension by which to extrude. In some implementations, the user interface provider 205 can display a keyboard or keypad responsive to the request. For example, the user interface provider 205 can cause display of the keypad 305 on the user device 101 for the user 107 to use the keypad 305 to provide the alphanumeric inputs. Without the user device 101 executing the application 203, the user 107 would have to utilize the keyboard 106 of the computing device 104 (e.g. move their right hand from the computer mouse 103 to the keyboard 106 or utilize their left hand to type). The application 203 executing on the user device 101 allows the user 107 to maintain one of their hands on the user device 101 enabling both hands to keep working.

Referring back to FIG. 3A in conjunction with FIG. 2, the user interface 102A can include a menu 304 button for customizing the text for the labels 303 of the buttons 302 or accessing tutorials and other settings. Referring now to FIG. 3C in conjunction with FIGS. 2 and 3A, an implementation of a user interface 102C is shown including a menu interface displayed on the user device 101 to manipulate the multi-dimensional model 105 maintained by the computing device 104. The user interface provider 205 can display the user interface 102C responsive to selection of the menu 304 button. The menu interface can provide selections such as button labels 303 for customization of the text for the labels 303 of the buttons 302 for the hotkeys 210, configuring hotkeys 307 for customization of the commands sent from the hotkeys 210 and settings, and gesture sensitivity 308 for customization of the sensitivity for handling the touch data from the user 107. In an example, the user interface 102C can include tutorials for using the application 203. In another example, the user interface provider 205 can display a user interface 102 for configuring the hotkeys 210 responsive to selection of the configuring hotkey 307 button. Configuring the hotkey can include the application 203 can receive, via the user interface 102, clicks or selections of the hotkey portion of the user interface 102 to set a particular hotkey as a keyboard shortcut for a specific function.

Referring now to FIG. 3D in conjunction with FIGS. 2 and 3A, an implementation of a user interface 102D is shown including button labels 309 displayed on the user device 101 to manipulate the multi-dimensional model 105 maintained by the computing device 104. In some implementations, the user interface provider 205 can display, on the screen of the user device 101, a request to configure the button 302. The user interface provider 205 can display the user interface 102C responsive to selection of the button labels 306 button. The user interface 102C can be a hotkey label screen for enabling the user 107 to customize the name or labels 303 of the buttons 302 of the hotkeys 210. In some implementations, the user interface provider 205 can receive, subsequent to the request to configure the button 302, alphanumeric input corresponding to the label 303 of the button 302. The custom labels 303 can receive text or names from the user 107 for each macro or hotkey 210 set for that specific button 302. In another example, the application 203 can receive, via the user interfaces 102, adjustments to the number of hotkey buttons 302 or commands and the appearance of the labels 303 or the hotkeys 210. In some implementations, the user interface provider 205 can generate or store, based on the alphanumeric input, the labels 303 associated with the button 302.

The user interface provider 205 can display a user interface 102 responsive to selection of the configure hotkeys 307 button. In some implementations, the user interface provider 205 can display, on the screen of the user device 101, a request to configure the functionality of the button 302. In some implementations, the user interface provider 205 can receive, subsequent to the request to configure the button 302, alphanumeric input corresponding to the label 303 of the button 302. For example, the alphanumeric input can be keypresses such as “7” to specify a scaling factor. In some implementations, the user interface provider 205 can generate or store, based on the alphanumeric input, the predetermined instruction 211 associated with the button 302 for the hotkey 210 for manipulating the digital object in the digital space.

Referring now to FIG. 3E, shown is an implementation of a user interface 102E including gesture sensitivity settings displayed on the user device 101 to manipulate the multi-dimensional model 105 maintained by the computing device 104. The user interface provider 205 can display the user interface 102E responsive to selection of the gesture sensitivity 308 button. The user interface 102E can indicate the sensitivities as adjustable sliders 310-312. The application 203 can receive adjustments to the sensitivity via the user interface 102E. Adjusting the sensitivity can cause the application 203 to apply a different multiplier or scaling factor for each six degree of freedom manipulation (e.g., zoom, pan, or rotate).

The application 203 can store these values in the database 209. For example, the sensitivity values can be stored as saved key value pairs. If the same user device were to be used with a different computing device, then the same sensitivity values manipulated with a scaling factor could be applied to instructions 211 transmitted to the different computing device. This approach enables the user 107 to optimize the sensitivity values based on how they prefer to use touch screens as these sensitivity values will be used to determine the scaling factor for each of the six degrees of freedom manipulation.

The input handler 206 of the application 203 can handle the touch data from the gesture handler 201 to identify inputs of the user 107. In some implementations, the input handler 206 can receive, from the gesture handler 201 of the user device 101, an identification of an input received by the screen of the user device 101. The input handler 206 can identify that the inputs are movements within the six degrees of freedom in the manipulation area 301. The six degrees of freedom can be defined as the rotating, panning, or zooming of the model 105 or digital space.

The input handler 206 can identify various touch inputs. For example, the input handler 206 can identify that input from the user 107 includes a double tap of two fingers. In another example, the input handler 206 can identify that input from the user 107 includes a double tap of one finger. In another example, the input handler 206 can identify that input from the user 107 includes a two finger pinch. In another example, the input handler 206 can identify that input from the user 107 includes a one finger drag. In another example, the input handler 206 can identify that input from the user 107 includes a two finger drag.

The input handler 206 can identify inputs corresponding to hotkeys 210 or predetermined functions. In some implementations, the input handler 206 can receive, from the gesture handler 201 of the user device 101, a selection of the button 302 on the user device 101. When the user 107 selects the buttons 302, the gesture handler 201 can detect touch data corresponding to the selection. The input handler 206 can identify the selection of a particular button 302 based on the gesture handler 201.

The input handler 206 can handle multiple inputs. For example, the input handler 206 can identify a double tap of the six degrees of freedom manipulation area with one finger or double tapping with two fingers. In another example, the input handler 206 can identify two-finger double taps. The input handler 206 can identify such inputs by identifying two taps on the screen within an amount of time configured in the operating system of the user device 101. For example, the input handler 206 can identify such inputs by identifying two taps on the screen within an amount of time configured in the operating system (e.g., 500 milliseconds). Such inputs can correspond to instructions 211 to re-center the model 105. In some implementations, the identification is a first identification and the input is a first input. In some implementations, the input handler 206 can receive, from the gesture handler 201 of the user device 101, a second identification of a second input received by the user device 101. For example, the first input can be a first tap or first finger of the user 107, and the second input can a second tap or second finger of the user 107.

The input handler 206 can process, handle, or receive voice or audio inputs. In some implementations, the input handler 206 can receive, from the audio handler 202 of the user device 101, the identification of the input received by a microphone of the user device 101. For example, the input handler 206 can convert audio of keypresses (e.g., user says “Control S”) to instructions 211 that include the keypresses (e.g., CTRL+S). In another example, For example, the input handler 206 can identify that the user 107 said “zoom the model by a scaling factor of 2.”

The instruction generator 207 can use the inputs to generate the instructions 211 to transmit to the computing device 104. The instruction generator 207 can generate instructions 211 for manipulating a digital object in a digital space. The instruction generator 207 can generate the instructions 211 based on the identification of the inputs from the user 107 by the input handler 206. The instruction generator 207 can generate instructions 211 from the inputs to re-center, enter input, rotate, pan, or zoom the model 105 or digital space with the model 105, among other instructions. For example, the instruction generator 207 can generate instructions 211 to re-center the model based on the identified input corresponding to a double tap of two fingers. In another example, the instruction generator 207 can generate instructions 211 to enter input based on the identified input corresponding to a double tap of one finger. In another example, the instruction generator 207 can generate instructions 211 to zoom the model 105 based on the identified input corresponding to a two finger pinch. In another example, the instruction generator 207 can generate instructions 211 to rotate the model 105 based on the identified input corresponding to a one finger drag. In another example, the instruction generator 207 can generate instructions 211 to pan the model 105 based on the identified input corresponding to a two finger drag.

The instruction generator 207 can process the raw touch data to generate the instructions 211 that includes the associated values or parameters for a command to manipulate the model 105. For example, the instructions 211 for zoom would only include the scaling factor, as well as the zoom identifier. In another example, the instructions to rotate includes the x and y rotation values. In yet another example, if one finger drag-to-rotate was the gesture processed by the user device 101, then the user device 101 can send x and y coordinates for rotation as well as the rotation command in the form of instructions 211 to be parsed by the computing device 104.

The instruction generator 207 can use the inputs to generate the instructions 211 for rotating the model 105. In some implementations, the instruction generator 207 can generate the instructions 211 to include a rotation identifier and coordinates for rotating the digital object in the digital space. In some implementations, the instruction generator 207 can generate the instructions 211 to include a rotation identifier and coordinates for rotating the digital space (e.g., the entire view and not the object). In another example, the instructions to rotate includes the x and y rotation values. In yet another example, if one finger drag-to-rotate was the gesture processed by the input handler 206, then the instruction generator 207 can generate instructions 211 with the rotation identifier with x and y coordinates for rotation to be parsed by the driver 213. An example of the generated instructions 211 can be “rx0123.4y0567.8q,” where the “r” means rotate based on the x and y coordinates as mentioned followed by their respective manipulation values. The “q” can be a terminating character. These coordinates of x and y are based on the movement of the one finger input in the x and y direction on the screen of the user device 101.

The instruction generator 207 can use the inputs to generate the instructions 211 for zooming the model 105. In some implementations, the instruction generator 207 can generate the instructions 211 to include a zoom identifier and a scaling factor for zooming in the digital space. For example, the instructions 211 for zooming would only include the scaling factor and the zoom command. In another example, if the command is a two-finger pinch to zoom, then the instruction generator 207 can generate instructions 211 that include a zoom identifier and a scaling factor to be parsed by the driver 213. The instruction generator 207 can determine the scaling factor from the sensitivity value that is programmed by the user 107 (e.g., FIG. 3E) and can be based on the amount of movement the user device 101 receives from two fingers of the user 107 moving together (zoom in) or away from one another (zoom out). The generated instructions 211 can include a “z” corresponding to zooming the model 105, and the instructions 211 can be z [scaling factor] q. The user device 101 determines this scaling factor from the sensitivity value that is programmed by the user 107 and can be based on the amount of movement the user device 101 receives from two fingers of the user 107 moving toward (zoom in) or away from one another (zoom out).

The instruction generator 207 can generate instructions 211 to zoom the model based on the scaling factor. For example, the equation to translate the sensitivity value into a scaling factor can be ((scaling factor−1)*sensitivity value)+1. For rotate and translate, the instruction generator 207 can multiple the sensitivity value by a set amount to be modified into a scaling factor. The instruction generator 207 can perform the multiplication and include the result and associated manipulation values with the instructions 211 for the computing device 104. The instruction generator 207 can multiply the scaling factor by the model manipulation amount for each six degree of freedom command when the API 219 is called to communicate with the CAD package 220.

The instruction generator 207 can generate the instructions 211 to pan the model 105. In some implementations, the instruction generator 207 can generate the instructions 211 to include a pan identifier and a direction to pan within the digital space. For example, if the input handler 206 receives an input to pan, then the instruction generator 207 can generate the instructions 211 to pan based on the two coordinates of translation in the form of instructions 211 to be parsed by the driver 213. The pan can be based on the user 107 swiping two fingers in the same direction. For example, the greater the swipe, the greater the amount of distance the instructions 211 request the model 105 to be panned. The generated instructions 211 can include the instructions to pan based on the two coordinates of translation in the form of instructions 211 to be parsed by the computing device 104.

The instruction generator 207 can generate instructions 211 based on multiple inputs. In some implementations, based on receiving the first identification and the second identification within a predetermined amount of time, the instruction generator 207 can generate the instructions 211 for manipulating the digital object in the digital space. For example, for identifications of inputs within one second of each other, the instruction generator 207 can identify that the user 107 provided a double tap to the screen. The instruction generator 207 can generate instructions 211 corresponding to double taps, such as to re-center the model 105. For example, the instruction generator 207 can generate the instructions 211 with an identifier to re-center the model. In some implementations, the instruction generator 207 can retrieve, from the database 209, instructions 211 corresponding to double taps. For example, the instructions 211 can include commands for API calls for the CAD package 220 to re-center the model 105.

The instruction generator 207 can retrieve predetermined instructions 211 from the database 209. In some implementations, the instruction generator 207 can identify instructions 211 corresponding to the identification. For example, the instruction generator 207 can query the identification of the inputs in the database 209. The instruction generator 207 can compare the text generated from the audio signals to a list of available hotkeys 210, keyboard functions, or keyboard shortcuts maintained by the database 209. The user device 101 can identify if the text matches one of the hotkey commands or keyboard functions. The user device 101 can generate instructions 211 that include the matching hotkey commands or keyboard function. The instruction generator 207 can identify that instructions 211 of “zoom, scaling factor of 2” correspond to identification of audio input of “zoom the model by a scaling factor of 2.” The instruction generator 207 can retrieve the instructions 211 from the database 209 instructions 211 corresponding to the hotkey 210 for the button 302. In some implementations, the instruction generator 207 can generate, based on the predetermined instructions, the instructions 211 for manipulating the digital object in the digital space.

The instruction generator 207 can generate the instructions 211 based on the sensitivity values. The instruction generator 207 can manage, maintain, or retrieve sensitivities for the touch inputs received from the user 107. The instruction generator 207 can use the sensitivities to optimize how the touch inputs are processed depending on the user 107. For example, the instruction generator 207 can use the sensitivity sliders and values of the six degrees of freedom movement to cause differing movements of the model 105 depending on the sensitivity. For example, instruction generator 207 can generate instructions 211 from the sensitivity of 10 for a pan to move the model 10 times as far as it would if the sensitivity were a 1 with the same touch input. In another example, the sensitivity value can be based on a scaling factor.

The instruction generator 207 can apply the sensitivity values to the instructions 211. The sensitivity can represent a multiplier value for the six degrees of freedom manipulation. For instructions to rotate or translate, the instruction generator 207 can multiply the x and y by the sensitivity factor. For example, the amount the model 105 is supposed to rotate or translate is multiplied by the value for the sensitivity. The multiplication can be by the value or by a fraction of the value. For example, a sensitivity of 1 can cause the instruction generator 207 to multiply the six degrees of freedom movement by 0.5, a sensitivity of 2 can cause the instruction generator 207 to multiply it by 1, and a sensitivity of 4 can cause the instruction generator 207 to multiply it by 2. For instructions to zoom, the instruction generator 207 can multiply the scaling factor to zoom by the sensitivity factor.

The instruction generator 207 can process the inputs received via the keyboard or keypad 305. The instruction generator 207 can generate the instructions 211 that include the inputs, such as the alphanumeric text. For example, if the input handler 206 identified a selection of “7” on the keypad 305, then the instruction generator 207 can generate the instructions 211 to include the “7”.

The instruction transmitter 208 can transmit the instructions 211 to the computing device 104. In some implementations, the instruction transmitter 208 can transmit the retrieved instructions 211 to the computing device 104. In some implementations, the instruction transmitter 208 can transmit the instructions 211 to the driver 213 of the computing device 104 to manipulate display of the digital object (e.g., model 105) in the digital space maintained by the computing device 104. In some implementations, the instruction transmitter 208 can transmit, via the connection (e.g., Bluetooth or USB), the instructions 211 to the driver 213 of the computing device 104 to manipulate display of the digital object within the digital space maintained by the computing device 104. The instruction transmitter 208 can transmit to the driver 213 a single character of text to notify the driver 213 of an upcoming transmission of the instruction. For example, for instructions 211 derived directly from keyboard inputs or indirectly from audio signals, the instruction transmitter 208 can transmit the instruction 211 that includes the alphanumeric text, hotkey 210, or keyboard function. For example, if the input handler 206 received a selection of “7” on the keypad 305, then the instruction transmitter 208 can transmit an instruction 211 that includes the “7”. To maintain the connection between transmissions of instructions 211, the connection maintainer 204 can transmit a heartbeat message at predetermined intervals to the connection manager 214.

In another example, the instruction transmitter 208 can bypass the driver 213 and instead transmit instructions 211 directly to the CAD package 220 via the API 219. For example, the instruction transmitter 208 can transmit instructions 211 containing keypresses directly to the CAD package 220 via the API 219, such as via a command line interface or any other exposed API 219 of the CAD package 220.

The driver 213 of the computing device 104 can enable the user device 101 to manipulate the multi-dimensional model 105 maintained by the application 203 of the computing device 104. The driver 213 can be a program, an add-on, a plugin, or any other executable code for facilitating communications between the application 203 and the CAD package 220 via the API 219 of the CAD package.

The connection manager 214 of the driver 213 of the computing device 104 can maintain the connection with the user device 101. The connection can be via USB or Bluetooth. In one example, the connection manager 214 can establish the connection via the network 212, which can be the Internet, Wi-Fi, or Cellular (e.g., 2G, 3G, 4G, and 5G).

The connection manager 214 can receive a request from the user device 101 to establish the connection. In some implementations, the connection manager 214 can receive, a request to from the user device 101 to connect via Bluetooth or USB. The connection manager 214 can respond to the user device 101 with an acknowledgment message responsive to receiving a heartbeat message. In some implementations, connection manager 214 can transmit, a response to the user device 101 to establish a connection with the user device 101 via Bluetooth or USB. If the computing device 104 (e.g., desktop/laptop) does not receive a heartbeat from the user device 101, the connection manager 214 can enter a mode where it will try to connect to the user device 101.

The connection manager 214 can cause the application 203 to display the keypad 305 or keyboard to provide inputs for the CAD package 220. The connection manager 214 can check at a variable rate to determine whether a text box is open in the CAD package 220 by calling a function via the API 219 to the CAD package 220. The connection manager 214 will receive a true value if a text box is open. For example, the CAD package 220 can display a text box for the user 107 to provide input. In yet another example, the connection manager 214 can detect that the CAD package 220 on the computing device 104 can receive inputs via the keypad 305 because the CAD package 220 opened a settings window or the command provider 218 provide an extrude command and the CAD package 220 requested a dimension by which to extrude.

If an alphanumeric text box is open within the CAD package 220 on the computing device 104, then the connection manager 214 can receive a request from the CAD package 220 via the API 219. In some implementations, the connection manager 214 can identify, a request by the CAD package 220 (e.g., application) for alphanumeric input. For example, if it the keyboard is open, then the true value can be sent to the user device 101 to cause the user device 101 to display the keyboard or keypad 305. In another example, the connection manager 214 can cause display of the keypad 305 responsive to functions being called within the CAD package 220 of the computing device 104. In some implementations, the connection manager 214 can transmit the request for alphanumeric input to the user device 101. The request can specify whether alphanumeric input or integer input is requested.

By requesting the user 107 to provide inputs via the application 203, the driver 213 allows the user 107 to maintain one of their hands on the user device 101 to enable both hands to keep working instead of having to utilize the keyboard 106 of the computing device 104 (e.g. move their right hand from the computer mouse 103 to the keyboard 106 or utilize their left hand to type).

The instruction receiver 215 of the driver 213 can receive the instructions 211 from the instruction transmitter 208 of the application 203 of the user device 101. In some implementations, instruction receiver 215 can receive, via the connection (e.g., Bluetooth or USB), the instructions 211 to manipulate display of the digital object in the digital space maintained by the CAD package 220 (e.g., application) of the computing device 104. In some implementations, the instruction receiver 215 of the driver 213 can receive, from the user device 101, the instructions 211 to manipulate display of the multi-dimensional model 105 maintained by the CAD package 220 of the computing device 104.

The instruction receiver 215 can execute loops to check for information from the user device 101. For example, the instruction receiver 215 can receive instructions 211 by executing the loop at a variable rate to check for new instructions 211 from the user device 101. The instruction receiver 215 can execute the loop to constantly check for data from the user device 101. For example, the instruction receiver 215 can execute a while loop that waits for instructions 211 to arrive for processing. The loop can depend on the connection status to the user device 101. For example, the loop can execute when the user device 101 and the computing device 104 are connected, exit when the devices disconnect, and again execute when the devices reconnect. The computing device 104 can process the information and send the same command whether communicating with a user device 101 made utilizing Android (Google of Alphabet, Inc. of Mountain View, Calif.) or Apple (of Cupertino, Calif.) Operating System.

The instruction parser 216 of the driver 213 can parse the instructions 211. For example, the instruction parser 216 can identify that the instructions 211 include keypresses “CTRL+ALT+Shift+F20”. The instruction parser 216 can parse instructions 211 received from user devices 101 having various operating systems, such as iOS and Android. For example, the order of the numbers in the instructions 211 can be device specific, so the instruction parser 216 can extract specific numbers referenced for each specific action. The instruction parser 216 can take the first letter of the instructions 211 to identify that action. For example, the instruction parser 216 can receive six degree of freedom manipulation information included in the instructions 211 from the user device 101. In some implementations, the instruction parser 216 can identify, from the instructions 211, a zoom identifier and scaling factor. In some implementations, the instruction parser 216 can identify, from the instructions 211, a rotation identifier and coordinates on a screen of the user device 101. For example if the instructions 211 includes the letter “r”, then the instruction parser 216 can identify that the model is to be rotated. In some implementations, the instruction parser 216 can identify, from the instructions 211, a pan identifier and a direction to pan in the digital space. For example if the instructions 211 include the letter “t”, then the instruction parser 216 can identify that the model is to be translated or panned. In another example, the instruction parser 216 can identify that the instructions 211 include a request to re-center the model. In yet another example, the instruction parser 216 can identify that the instructions 211 include a request to call a hotkey. For example, if the user device 101 transmitted instructions 211 that identify a keyboard selection of “7”, then the instruction parser 216 can receive the instructions 211 that include the “7”.

The instruction parser 216 can process or parse instructions 211 based on the audio signals. For example, the instruction parser 216 can include a list of available hotkeys 210, keyboard functions, or keyboard shortcuts. The user device 101 can include the processed audio inputs in the instructions 211 provided to the instruction parser 216, which can compare the text to the list. For example, the instruction parser 216 can match the instructions 211 including “zoom the model by a factor of 2” to a command to zoom the model by 2.

The command generator 217 of the driver 213 can generate a command based on the instructions 211. In some implementations, the command generator 217 can generate, based on the instructions 211, a command for manipulating a digital object in a digital space. For example, the command generator 217 of the driver 213 can generate the command to include the keypresses “CTRL+ALT+Shift+F20”. The command generator 217 can generate the command to transmit to the CAD package 220 via the API 219. For example, the command generator 217 can include the parsed values in the command that is sent to the CAD package 220 via the API 219. The API 219 can be unique or designed for the CAD package 220. The command generator 217 can download the API 219 for CAD package 220. The API 219 can include a list of functions that can be called to the CAD package 220. The command generator 217 can generate the command based on the supported functions.

The command generator 217 can perform or generate calculations based on the instructions 211 to generate the command. The command generator 217 can communicate with the CAD package 220 via the API 219 to generate the command. In some implementations, the command generator 217 can identify a center of rotation for the digital object in the digital space. For example, if the instructions 211 include a rotation command, then the command generator 217 can determine if a center of rotation needs to be calculated based on whether the model has been translated since the last rotation. The command generator 217 can store a status (e.g., single Boolean) of whether the center of rotation needs to be recalculated.

The command generator 217 can execute loops to check for information from the CAD package 220. The command generator 217 can detect that the center to need to be rotated based on a variety of events such as opening a new document in the CAD package 220. In another example, if the command generator 217 generates a command that triggers the status (e.g., translation command), then the command generator 217 can change the status (e.g., set to true) to indicate that a new center of rotation needs to be recalculated. If the model has not been translated, then the command generator 217 can retrieve a stored center of rotation.

If a new center of rotation needs to be calculated for a 3D body (because the model 105 has been translated), then the command generator 217 can return the screen pixels representing the corners of the visible CAD display 220. The command generator 217 can obtain points corresponding to the screen pixels by calling a command via the API 219 to the CAD package 220. For example, the command generator 217 can obtain points that are halfway on x and y axis and provide the midpoints of the visible display. An example of SolidWorks API 219 is System.object GetVisibleBox( ). The command generator 217 can assign a three-dimensional point at the center of this rectangle (e.g., a view of the digital space on the screen) with a Z value of 0 (assuming X, Y represent the center value). In some implementations, the command generator 217 can generate a second point having three-dimensional coordinates, the second point forming a vector that is normal to a z-axis of the digital space displayed on the screen of the computing device 104. The command generator 217 can assign a second value with Z=1 to create a series of points that if combined into a ray would be normal to the screen. The command generator 217 can store the values in memory or local storage.

The command generator 217 can translate these two points from pixel coordinates on the screen into model coordinates in the CAD package 220 through a direct function within the API 219 of the CAD package 220. In some implementations, the command generator 217 can generate coordinates of the digital space based on the coordinates on the screen of the user device 101. The command generator 217 can execute a function to convert the screen coordinates into model coordinates in the CAD package 220. The command generator 217 can create a ray in model coordinates from these two newly assigned model coordinate points. In some implementations, the command generator 217 can assign, based on the first point and the second point, one or more bounding boxes to the digital object in the digital space. For each discrete 3D body on the screen, the command generator 217 can assign a bounding box provided by the CAD package 220 as AABB coordinates in three dimensions. For example, to assign the bounding box, the command generator 217 can make an API call of an axis aligned bounding box. In some implementations, the command generator 217 can identify pixel identifiers at each corner of the digital space displayed on a screen of the computing device 104. To define an axis aligned bounding box, the computing device 104 can take two points from the xyz min and xyz max to define the six-planed prism. In some implementations, the command generator 217 can identify, based on the pixel identifiers, a first point having three-dimensional coordinates at a center of the digital space. These two three-dimensional model points represent the corners of the bounding box in three-dimensional space.

The command generator 217 can filter the bounding boxes based on intersections with the ray into the screen. In some implementations, the command generator 217 can identify, one or more intersections between the one or more bounding boxes and the vector. The command generator 217 can include the bounding boxes with an intersection. In some implementations, the command generator 217 can identify, based on the one or more intersections, the center of rotation for the digital object in the digital space. The command generator 217 can return the nearest intersection point of these bounding boxes to the surface of the screen as the center of rotation for the model. In some implementations, the command generator 217 can generate, based on the coordinates on the screen of the user device 101 and the center of rotation, the command comprising a rotation request for rotating the digital object in the digital space. Once the command generator 217 calculates or identifies the center of rotation, the command generator 217 can provide the coordinates for center of rotation (x, y, and z) as well as degrees of rotation (x and y) to the CAD package via the API 219. In some implementations, the command generator 217 can generate, based on the instructions 211, the command comprising a rotation request and the coordinates of the digital space. The command generator 217 can instruct the CAD program to rotate the model about that point by the amount supplied in the instructions 211 from the user device 101. The command generator 217 can store the center of rotation for future use.

If command generator 217 fails to find a center of rotation, then the computing device 104 can use the center of mass of the body in the CAD package 220. The command generator 217 can call or retrieve the center of mass from the CAD package 220 via the API 219. The command generator 217 can call or retrieve the degrees of rotation (x and y) in the CAD package 220 through a direct command referenced from the CAD package 220 via the API 219. The command generator 217 can generate a command to rotate the model based on the coordinates.

The command generator 217 can generate a command from the instructions 211 to zoom the model. In some implementations, the command generator 217 can generate, based on the instructions 211, the command comprising a zoom request and the scaling factor for zooming in the digital space. If the application 203 transmits an instruction that includes a request to zoom the model 105, then the command generator 217 can receive the instruction and parse out or identify the zoom request and the associated scaling factor (and create a scaling factor from that value). For example, the command generator 217 can identify the zoom distance in the instruction 211.

The command generator 217 can generate a command from the instructions 211 to pan the model. In some implementations, the command generator 217 can generate, based on the instructions 211, the command comprising a pan request and the direction to pan in the digital space. If the application 203 transmits instructions 211 that include a pan command along with the coordinates of translation, then the command generator 217 can receive the instructions 211 and parse out or identify the pan request and the x and y coordinates for translation. The command generator 217 can generate a command to pan the model 105 based on the x and y coordinates for translation. The command generator 217 can obtain the amounts that are provided in the instructions 211 from the application 203, and generate a command to pan the model by that amount (multiplied by scaling factor). The six degrees of freedom commands generated by the command generator 217 can be relative to where the model 105 is in space. For example, the command does not indicate that the model 105 move to a specific 3D location, but indicates how much the model is to move.

The command generator 217 can generate a command from the instructions 211 based on keypresses. For example, if the user device 101 received a selection of “7” on its keyboard, then the command generator 217 can generate a command that includes a keypress of “7” to mimic the typing of the command on the keyboard of the command generator 217.

The command provider 218 of the driver 213 can provide the command via the API 219 to the CAD package 220. In some implementations, the command provider 218 can provide the command to the CAD package 220 (e.g., application) to manipulate the digital object in the digital space. For example, the command provider 218 of the driver 213 can provide the hotkeys 210 into the CAD package 220 using a specific keyboard text command through the user interface 102 such as “CTRL+ALT+Shift+F20”.

The command provider 218 can provide the command to the CAD package 220 via the API 219. The command provider 218 can provide the command for the specific manipulation of the model 105. The command provider 218 can communicate directly with the CAD package 220 via the API 219 or by providing commands that mirror the keyboard inputs from the user device 101. For example, the command provider 218 can provide a specific keyboard text command through the user interface 102 such as CTRL+ALT+Shift+F20. In another example, if the user device 101 receives a selection of “7” on its keyboard, then the command provider 218 can transmit a command that includes a keypress of “7” as though as the command was typed on the keyboard of the command provider 218.

The command provider 218 can provide the commands with hotkeys 210 to the CAD package 220 via the API 219. For example, the hotkeys 210 can include a function to re-center the model 105. In another example, the hotkeys 210 can include custom macros made by the user 107 or customized for the CAD package 220. The command provider 218 can call these commands as hotkeys via either the keyboard input or via the API 219 of the CAD package 220 to re-center the model 105. If the command is to pan the model 105, the command provider 218 can call the API function for translation and include the x and y coordinates based on the parsed instruction received from the user device 101. If the command is to zoom the model 105, the command provider 218 can call the API function to zoom the model 105 based on the scaling factor included in the command. If the command is to rotate the model 105, the command provider 218 can call the API function to rotate the model 105 based on the coordinates included in the command.

The command provider 218 can provide the commands to the CAD package 220 while the CAD package 220 receives other inputs, such as from a keyboard or computer mouse 103 of the command provider 218. Because the command provider 218 provides the commands to the CAD package 220 via the API 219, the commands (e.g., six degrees of freedom manipulations) will not override the computer mouse 103 or keyboard 106 inputs. The CAD package 220 can use the commands in tangent with the computer mouse 103 or keyboard 106 inputs. The CAD package 220 can process the commands and other inputs simultaneously.

If the command provider 218 provides a command corresponding to a hotkey selected on the user device 101, the predetermined keyboard shortcut can be translated by the command provider 218 to a virtual keyboard input and provided to the CAD package 220 as a virtual keyboard input. This the command provider 218 can perform this translation through functionality within the command provider 218 that mimics a keyboard input.

The command provider 218 of the application 203 can verify that the CAD package 220 is in an open or active window capable of receiving the command before providing the command. Through a command listed in the API 219 of the CAD package 220, the command provider 218 can verify that the CAD package 220 has an open window on the command provider 218. For example, the command provider 218 can call an operating system function to identify the active window. If the active window corresponds to the CAD package 220, then the command provider 218 can provide the command via the operating system library. By verifying the presence of the open window, the command provider 218 can ensure that if a command corresponding to a hotkey is provided, then the CAD package 220 can receive and execute the command. If there was no open window, then the command, in effect, would be blocked.

For commands derived from the keyboard inputs, the driver of the command provider 218 can send the text from the keyboard 106 with the CAD package 220 similarly to how the hotkeys 210 and enter command are sent. The driver of the command provider 218 can provide the virtual keyboard inputs after confirming that the CAD package 220 has the window opened.

The API 219 corresponding to the CAD package 220 can enable the driver 213 to communicate with the CAD package 220, such as to provide commands to manipulate the model maintained by the CAD package 220. In another example, the API 219 enables the application 203 to bypass the driver 213 such that the API 219 can receive instructions 211 directly from the instruction transmitter 208. For example, the API 219 can receive instructions 211 containing keypresses directly from the instruction transmitter 208 and process the instructions 211 via a command line interface or any other exposed API of the CAD package 220.

The CAD package 220 of the computing device 104 can maintain the model 105. The CAD package 220 can include, but not limited to, SolidWorks (Dassault Systèmes of Dassault Group of Paris, France) or Autodesk Fusion (Autodesk Inc., Mill Valley, Calif.). The CAD package 220 can include an API 219.

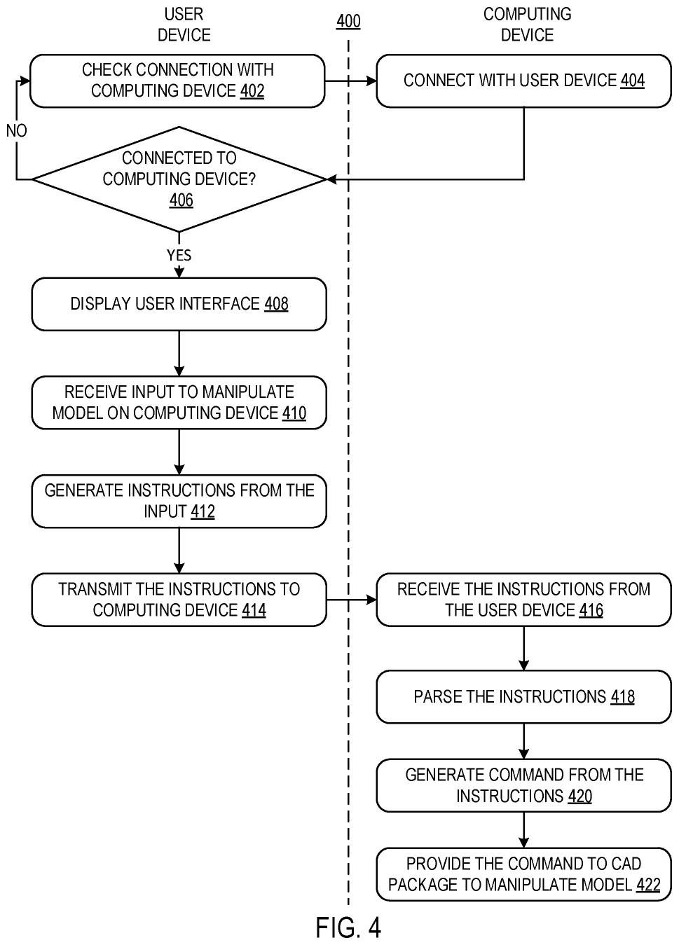

Referring now to FIG. 4, shown is a flow diagram of an implementation of a method for the user device to manipulate the multi-dimensional model maintained by the computing device. A user device (e.g., user device 101) and a computing device (e.g., computing device 104), or any other computing devices can execute, perform, or otherwise carry out the method 400. Components described in FIGS. 1-3 and detailed above can perform the operations and functionalities of the method 400. In brief overview, the user device can check a connection a computing device (STEP 402). The computing device can connect with the user device (STEP 404). The user device can verify the connection with the computing device (STEP 406). The user device can display a user interface (STEP 408). The user device can receive input to manipulate a model on the computing device (STEP 410). The user device can generate instructions from the input (STEP 412). The user device can transmit the instructions to the computing device (STEP 414). The computing device can receive the instructions from the user device (STEP 416). The computing device can parse the instructions (STEP 418). The computing device can generate a command from the instructions (STEP 420). The computing device can provide the command to a CAD package to manipulate the model (STEP 422).

Still referring to FIG. 4 and in further detail, the user device can check a connection a computing device (STEP 402). The user device can establish or maintain a connection with the computing device. The connection can be via USB or Bluetooth. Connections via USB can be established via Transport Control Protocol (TCP). In one example, the user device can establish the connection via a network (e.g., network 212), which can be the interne, Wi-Fi, or Cellular (e.g., 2G, 3G, 4G, and 5G).

The computing device can connect with the user device (STEP 404). In some implementations, the computing device can receive, a request to from the user device to connect via Bluetooth or USB. The computing device can respond to the user device with an acknowledgment message responsive to receiving a heartbeat message. In some implementations, computing device can transmit, a response to the user device to establish a connection with the user device via Bluetooth or USB. The computing device can maintain the connection with the user device. The connection can be via USB or Bluetooth. In one example, the computing device can establish the connection via the network, which can be the internet, Wi-Fi, or Cellular (e.g., 2G, 3G, 4G, and 5G).

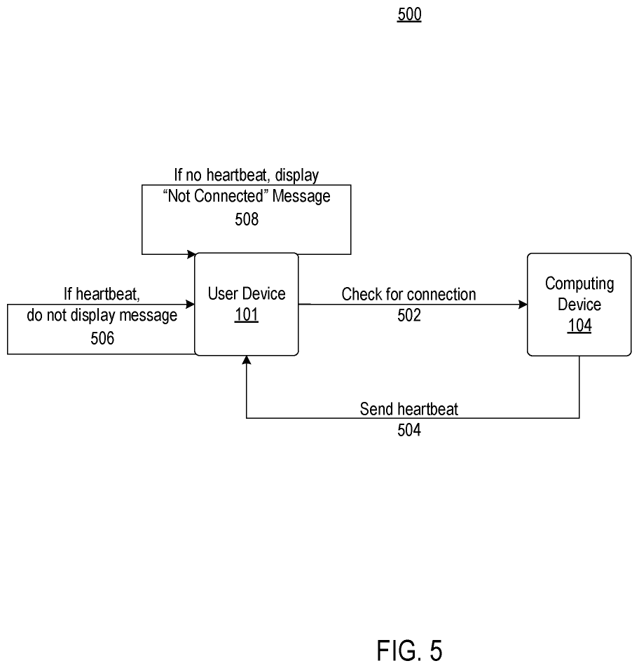

The user device can verify the connection with the computing device (STEP 406). Referring now to FIG. 5 in conjunction with FIG. 4, FIG. 5 shows a flow diagram of an implementation of a method 500 for the user device to maintain a connection with the computing device. The user device can check for a connection with the computing device (STEP 502). The user device can verify a connection with the computing device. The verification can be different depending on the operating system of the user device. For example, a user device executing Android can transmit a heartbeat message every half second to notify the computing device of the connection. The computing device can send a heartbeat (STEP 504). The computing device can respond to the user device with an acknowledgment message responsive to receiving a heartbeat message. If the computing device (e.g., Computer/Desktop) does not receive a heartbeat it can return to a mode where it will try to connect to the user device. The user device does not display a message responsive to receiving the heartbeat (STEP 506). The user device can display a “not connected” message whenever it does not receive an acknowledgment message STEP 508). The user device can display a “not connected” message whenever it does not receive an acknowledgment message within a predetermined amount of time (e.g., two seconds). In another example, when the connection disconnects, the “not connected” message can be displayed. The user device executing iOS can establish a USB connection with a TCP channel to send commands. For Bluetooth connections, the user device can verify the connection similarly to that of Android. In yet another example, the user device can connect with the computing device via Wi-Fi. The connection via Wi-Fi or USB can be a TCP connection.

Referring back to FIG. 4, the user device can display a user interface (STEP 408). In some implementations, the user device can display, on the screen of the user device, a manipulation area for controlling display of the multi-dimensional model maintained by the computing device. The manipulation area of the user interface can be the area for the user to provide touches to manipulate the model. The user device can handle the touches received from the user in the manipulation area.

The user interface can include buttons corresponding to the hotkeys. The hotkeys can define functionality that the user can define as specific commands or custom-made commands (macros) into each of the buttons. The hotkeys can correspond to any command that is in the CAD package or custom-made commands (macros). For example, the hotkeys can specify keypresses such as “CTRL+ALT+Shift+F20”. Other examples of commands that can be included in the hotkeys include “Extrude”, “Cut”, or “Sketch.” Yet another example of pre-programmed hotkeys including “Enter” or re-centering the model within the CAD package. In some implementations, the user interface provider can display, on the screen of the user device, a button corresponding to the instructions for controlling the model. Another configuration for hotkeys could include having all available hotkeys within the user device that would send the instructions to the computing device, which would then call the specific CAD package via the API corresponding to the selected function in the instructions. In some implementations, the user device can maintain the instructions corresponding to the hotkeys for manipulating the digital object in the digital space.

The user interface can include labels for each of the buttons. The user device can receive, via the user interfaces, text corresponding to the labels for these buttons. The labels can correspond to the name of the function or custom command that the user wishes to program into each specific hotkey.

The user interface can include a keypad displayed on the user device to manipulate the multi-dimensional model maintained by the computing device. They keypad can be a pop-up keypad. It is contemplated that the user interface can include a keyboard. The user interface provider can cause display of the user interface including the keypad. In one example, the user interface provider can provide, display, or generate the keypad after a specific button corresponding to the hotkey is selected. In another example, the user interface provider can cause the operating system of the user device to display the keypad.

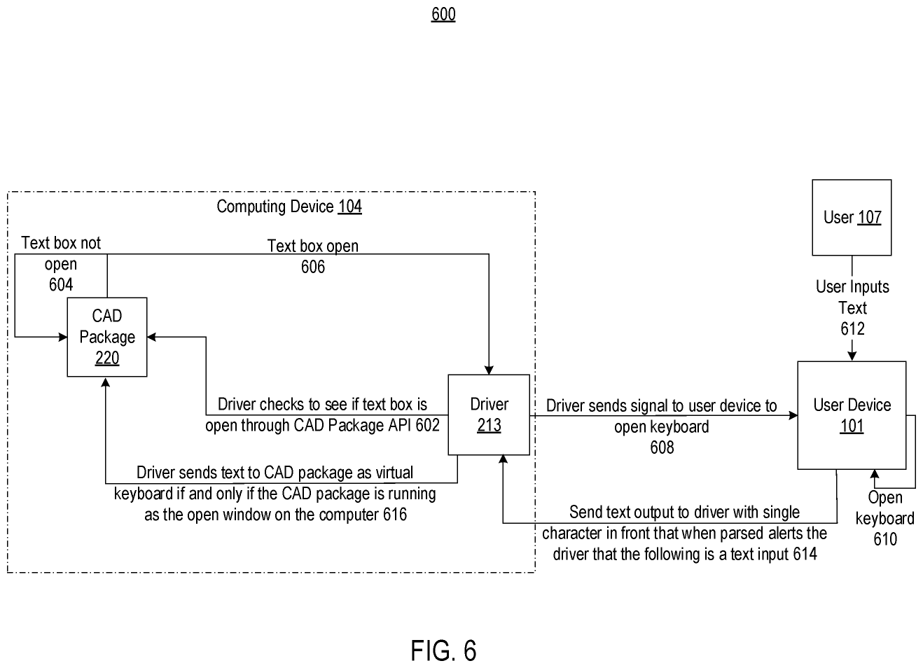

Referring now to FIG. 6 in conjunction with FIG. 4, FIG. 6 shows a flow diagram of an implementation of a method 600 for using a keyboard on the user device to manipulate the multi-dimensional model maintained by the computing device. The driver of the computing device can check to see if text box is open through the API of the CAD package (STEP 602). The computing device can check at a variable rate to determine whether a text box is open in the CAD package by calling a function within the API of the CAD package that will return true if a text box is open. The computing device can determine that the text box is not open (STEP 604). Conversely, the computing device can determine that the text box is open (STEP 606). In some implementations, the computing device can identify, a request by the CAD package (e.g., application) for alphanumeric input. If an alphanumeric text box is open within the CAD package on the computing device, then the CAD package can transmit a request to the driver of the computing device. The driver of the computing device can transmit requests to the user device to open the keyboard (STEP 608). In some implementations, the computing device can transmit the request for input to the user device for the alphanumeric input. The request can specify whether alphanumeric input or integer input is requested. If the keyboard is open, then the true value can be sent to the user device to cause the user device to display the keyboard. The computing device can then transmit the request to the user device to cause the user device to display the keyboard.

The user device can open the keyboard (STEP 610). The user device can include a thread waiting for the request. Upon receiving the request, the user device can display the keyboard to receive inputs via the displayed keyboard. The user device can cause display of the keypad responsive to functions being called within the CAD package of the computing device. In some implementations, the user device can receive, from the computing device, a request for alphanumeric input. For example, the user device can detect that the CAD package on the computing device can receive inputs via the keypad because the CAD package opened a settings window or the user on the computing device inputted an extrude command and the CAD package requested a dimension by which to extrude. In some implementations, the user device can display a keyboard or keypad responsive to the request.

As will be discussed with reference STEP 410, the user device can receive inputs from the user (STEP 612). For example, the user device can cause display of the keypad on the user device for the user to use the keypad to provide the alphanumeric inputs. Without the user device, the user would have to utilize the keyboard of the computing device (e.g. move their right hand from the computer mouse to the keyboard or utilize their left hand to type). The user device allows the user to maintain one of their hands on the user device to enable both hands to keep working. As will be discussed with reference STEPs 412-414, the user device can send text output to the computing device (STEP 614). For example, the user device can send text output with single character in front that when parsed alerts the computing device that the following is a text input. As will be discussed with reference STEPs 416-422, the computing device can provide the input to the CAD package (STEP 616). For example, the driver of the computing device can sends text to CAD package as virtual keyboard if and only if the CAD package is running as the open window on the computer.

Referring back to FIG. 4, the user device can display a menu button for customizing the text for the labels of the buttons or accessing tutorials and other settings. The user device can display the menu interface responsive to selection of the menu button. The menu interface can provide selections such as button labels for customization of the text for the labels of the buttons for the hotkeys, configuring hotkeys for customization of the commands sent from the hotkeys and settings, and gesture sensitivity for customization of the sensitivity for handling the touch data from the user. In an example, the user interface can include tutorials for using the application. In another example, the user interface provider can display a user interface for configuring the hotkeys responsive to selection of the configuring hotkey button. Configuring the hotkey can include the application can receive, via the user interface, clicks or selections of the hotkey portion of the user interface to set a particular hotkey as a keyboard shortcut for a specific function.

The user device can display a user interface for configuring including button labels. In some implementations, the user device can display, on the screen of the user device, a request to configure the buttons. The user device can display the user interface responsive to selection of the button labels button. The user interface can be a label interface for enabling the user to customize the name or labels of the buttons of the hotkeys. In some implementations, the user device can receive, subsequent to the request to configure the button, alphanumeric input corresponding to the label of the button. The text box can receive custom labels or names from the user for each macro or hotkey set for that specific button. In another example, the application can receive, via the user interfaces, adjustments to the number of hotkey buttons or commands and the appearance of the labels or the hotkeys. In some implementations, the user interface provider can generate or store, based on the alphanumeric input, the labels associated with the button.

The user device can display a user interface responsive to selection of the configure hotkeys button. In some implementations, the user device can display, on the screen of the user device, a request to configure the functionality of the button. In some implementations, the user device can receive, subsequent to the request to configure the button, alphanumeric input corresponding to the label of the button. For example, the alphanumeric input can be keypresses such as “7” to specify a scaling factor. In some implementations, the user device can generate or store, based on the alphanumeric input, the predetermined instruction associated with the button for the hotkey for manipulating the digital object in the digital space.

The user device can display a user interface including gesture sensitivity settings displayed on the user device to manipulate the multi-dimensional model maintained by the computing device. The user device can display the user interface responsive to selection of the gesture sensitivity button. Sensitivity can be defined as the amount of movement in the 3D model in six degrees of freedom per unit of movement of touch input. The user interface can indicate the sensitivities as adjustable sliders. The user device can receive adjustments to the sensitivity. The sensitivity can define a factor by which each manipulation (pan, zoom, or rotate) can be adjusted to the user's liking. Adjusting the sensitivity can cause the user device to apply a different multiplier, scaling factor, for each six degree of freedom manipulation (e.g., zoom, pan, or rotate). For example, increasing the sensitivity can increase the movement caused by input from the user. The user device can store these values in its database. In another example, when the user device generates instructions to call the appropriate six degree of freedom manipulation based on the received instructions, the user device can multiply that value by the scaling factor.

The sensitivity values can be stored by the user device. For example, the sensitivity values can be stored as saved key value pairs. If the same user device were to be used with a different computing device, then the same sensitivity values manipulated into a scaling factor could be applied to instructions transmitted to the different computing device. This approach enables the user to optimize the sensitivity values based on how they prefer to use touch screens as these sensitivity values will be used to determine the scaling factor for each six degree of freedom manipulation.

The user device can receive input to manipulate a model on the computing device (STEP 410). The inputs can be touch, haptic, or audio input data from the user making selections on the screen of the user device.

The user device can identify inputs corresponding to hotkeys or predetermined functions. In some implementations, the user device can receive, from the gesture handler of the user device, a selection of the button on the user device. When the user selects the buttons, the gesture handler can detect touch data corresponding to the selection. The user device can identify the selection of a particular button based on the gesture handler.

The user device can handle multiple inputs. For example, the user device can identify a double tap of the 6 degree of freedom manipulation area with one finger or double tapping with two fingers. In another example, the user device can identify two-finger double taps. The user device can identify such inputs by identifying two taps on the screen in an amount of time configured in the operating system of the user device. For example, the user device can identify such inputs by identifying two taps on the screen in an amount of time configured in the operating system (e.g., 500 milliseconds). Such inputs can correspond to instructions to re-center the model. In some implementations, the identification is a first identification and the input is a first input. In some implementations, the user device can receive, from the gesture handler of the user device, a second identification of a second input received by the user device. For example, the first input can be a first tap or first finger of the user, and the second input can a second tap or second finger of the user.

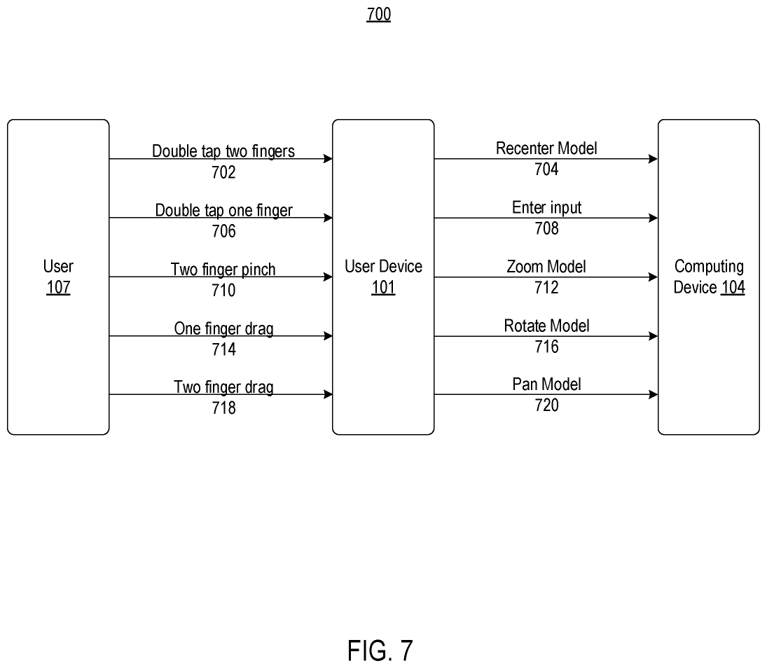

Referring now to FIG. 7 in conjunction with FIG. 4, shown is a flow diagram of an implementation of a method for the user device to handle user touch inputs to manipulate the multi-dimensional model maintained by the computing device. The user device can receive the raw touch data. The touch data from the user can be processed by the application. For example, the raw touch data could be 6 degrees of freedom manipulation that is processed by the user device. In particular, the application can map various touch inputs to generate the instructions for the computing device. The user device can receive an input from the user that includes a double tap of two fingers (STEP 702). As will be discussed in STEPS 412 and 414, the user device can convert this input to instructions for the computing device to re-center the model (STEP 704). The user device can receive an input from the user that includes a double tap of one finger (STEP 706). As will be discussed in STEPS 412 and 414, the user device can convert this input to instructions for the computing device to enter input (STEP 708). The user device can receive an input from the user that includes a two finger pinch (STEP 710). As will be discussed in STEPS 412 and 414, the user device can convert this input to instructions for the computing device to zoom the model (STEP 712). The user device can receive an input from the user that includes a one finger drag (STEP 714). As will be discussed in STEPS 412 and 414, the user device can convert this input to instructions for the computing device to rotate the model (STEP 716). The user device can receive an input from the user that includes a two finger drag (STEP 718). As will be discussed in STEPS 412 and 414, the user device can convert this input to instructions for the computing device to pan the model (STEP 720).

The user device can receive voice or audio inputs. The user device can receive audio inputs from an audio handler of the user device. In some implementations, the user device can receive, from the audio handler of the user device, the identification of the input received by a microphone of the user device. The user device can convert audio inputs to text. The user device can translate or convert the text to instructions for the CAD package. For example, the user device can convert audio of keypresses to instructions that include the keypresses. In another example, the user device can identify that the user said “zoom the model by a scaling factor of 2.”

Referring back to FIG. 4, the user device can generate the instructions from the input (STEP 412). The user device can use the inputs to generate the instructions to transmit to the computing device. The user device can generate instructions for manipulating a digital object in a digital space. The user device can generate the instructions based on the identification of the inputs from the user by the user device. The user device can generate instructions from the inputs to re-center, enter input, rotate, pan, or zoom the model or space with the model, among other instructions. For example, the user device can generate instructions to re-center the model based on the identified input corresponding to a double tap of two fingers. In another example, the user device can generate instructions to enter input based on the identified input corresponding to a double tap of one finger. In another example, the user device can generate instructions to zoom the model 105 based on the identified input corresponding to a two finger pinch. In another example, the user device can generate instructions to rotate the model 105 based on the identified input corresponding to a one finger drag. In another example, the user device can generate instructions to pan the model based on the identified input corresponding to a two finger drag.

The application can use the inputs to generate the instructions to transmit to the computing device. The user device can process the raw touch data to generate the instructions that includes the associated values or parameters for a command to manipulate the model. For example, the instructions for zoom would only include the scaling factor, as well as the zoom identifier. In another example, the instructions to rotate includes the x and y rotation values. In yet another example, if one finger drag-to-rotate was gesture processed by the user device, then the user device can send x and y coordinates for rotation as well as the rotation command in the form of instructions to be parsed by the computing device.

The user device can use the inputs to generate the instructions for rotating the model. In some implementations, the user device can generate the instructions to include a rotation identifier and coordinates for rotating the digital object in the digital space. In some implementations, the user device can generate the instructions to include a rotation identifier and coordinates for rotating the digital space (e.g., the entire view and not the object). An example of the instructions that could be sent from the user device to the computing device could be “rx0123.4y0567.8q,” where the “r” means rotate based on the x and y coordinates as mentioned followed by their respective manipulation values. The “q” can be a terminating character. These coordinates of x and y are based on the movement of the one finger input in the x and y direction on the screen of the user device.

The user device can use the inputs to generate the instructions for zooming the model. In some implementations, the user device can generate the instructions to include a zoom identifier and a scaling factor for zooming in the digital space. For example, the instructions for zoom would only include the scaling factor, as well as the zoom command. In another example, if the command is a two-finger pinch to zoom, then the user device can transmit a zoom request and a scaling factor in the form of instructions to be parsed by the computing device. In yet another example, “z” can correspond to zooming the model, and the instructions can be z [scaling factor] q. The user device determines this scaling factor from the sensitivity value that is programmed by the user and can be based on the amount of movement the user device receives from two fingers of the user moving together (zoom in) or away from one another (zoom out).

The user device can generate instructions to zoom the model based on the scaling factor. For example, the equation to translate the sensitivity value into a scaling factor can be ((scaling factor−1)*sensitivity value)+1. For rotate and translate, the user device can multiple the sensitivity value by a set amount to be modified into a scaling factor. The user device can perform the multiplication and include the result and associated manipulation values with the instructions for the computing device. The user device can multiply the scaling factor by the model manipulation amount for each six degree of freedom command when the API is called to communicate with the CAD package.

The user device can generate the instructions to pan the model. In some implementations, the user device can generate the instructions to include a pan identifier and a direction to pan in the digital space. For example, if the user device receives an input to pan, then the user device can transmit the instructions to pan based on the two coordinates of translation in the form of instructions to be parsed by the computing device. The pan can be based on the user swiping two fingers in the same direction. For example, the greater the swipe, the greater the amount of distance the model is panned. The generated instructions can include the instructions to pan based on the two coordinates of translation in the form of instructions to be parsed by the computing device.

The user device can generate instructions corresponding to hotkeys or predetermined functions. In some implementations, the user device can retrieve instructions corresponding to a selected button. The user device can transmit the predetermined instructions to the computing device to manipulate the digital object in the digital space. In some implementations, the user device can generate, based on the predetermined instructions, the instructions for manipulating the digital object in the digital space.

The user device can generate instructions based on multiple inputs. In some implementations, based on receiving the first identification and the second identification within a predetermined amount of time, the user device can generate the instructions for manipulating the digital object in the digital space. For example, for identifications of inputs within one second of each other, the user device can identify that the user provided a double tap to the screen. The user device can generate instructions corresponding to double taps, such as to re-center the model. For example, the user device can generate the instructions with an identifier to re-center the model. In some implementations, the user device can retrieve, from the database, instructions corresponding to double taps. For example, the user device can identify a double tap of the 6 degree of freedom manipulation area with one finger or double tapping with two fingers. In another example, the user device can identify two-finger double taps. The user device can identify such inputs by identifying two taps on the screen in an amount of time configured in the operating system (e.g., 500 milliseconds). Such inputs can correspond to instructions to re-center the model. The user device can generate the instructions with an identifier to re-center the model. For example, the instructions can include API calls for the CAD package (e.g., SolidWorks) to re-center the model.

The user device can retrieve predetermined instructions from the database. In some implementations, the user device can identify instructions corresponding to the identification. For example, the user device can query the identification of the inputs in the database. The user device can compare the text generated from the audio signals to a list of available hotkeys, keyboard functions, or keyboard shortcuts maintained by the database. The user device can identify if the text matches one of the hotkey commands or keyboard functions. The user device can generate the instructions that include the matching hotkey or keyboard function. The user device can identify that instructions of “zoom, scaling factor of 2” correspond to identification of audio input of “zoom the model by a scaling factor of 2.” The user device can retrieve the instructions from the database. The user device can retrieve, from the database, instructions corresponding to the hotkey for the button. In some implementations, the user device can generate, based on the predetermined instructions, the instructions for manipulating the digital object in the digital space.

The user device can generate the instructions based on the sensitivity values. The user device can manage or maintain sensitivities for the touch inputs received from the users. The user device can manage the sensitivities to optimize how the touch inputs are processed depending on the user. For example, the sensitivity sliders and values of the 6 degree of freedom movement can cause differing movements of the model 105 depending on the sensitivity. For example, the sensitivity of 10 a pan would move the model 10 times as far as it would if the sensitivity were a 1 with the same touch input. In another example, the sensitivity value can be based on a scaling factor.

The user device can apply the sensitivity values to the instructions. The sensitivity can represent a multiplier value for the 6 degree of freedom manipulation. For instructions to rotate or translate, the user device can multiply the x and y by the sensitivity factor. For example, the amount the model is supposed to rotate or translate is multiplied by the value for the sensitivity. The multiplication can be by the value or by a fraction of the value. For example, a sensitivity of 1 can cause the user device to multiple by 0.5, a sensitivity of 2 can cause the user device to multiply by 1, and a sensitivity of 4 can cause the user device to multiply by 2. The user device can perform the multiplication before sending instructions to the computing device. For instructions to zoom, the user device can multiply the scaling factor to zoom by the sensitivity factor.

The user device can process the inputs received via the keyboard. The user device can generate the instructions that include the inputs, such as the alphanumeric text. For example, if the user device received a selection of “7” on the keyboard, then the user device can generate the instructions to include the “7”.

The user device can process the text-inputs based on the audio signals. The user device can compare the text generated from the audio signals to a list of available hotkeys, keyboard functions, or keyboard shortcuts maintained by the user device. The user device can identify if the text matches one of the hotkey commands or keyboard functions. The user device can generate the instructions that include the matching hotkey or keyboard function.

The user device can transmit the instructions to the computing device (STEP 414). In some implementations, the user device can transmit the instructions to the driver of the computing device to manipulate display of the digital object (e.g., multi-dimensional model) in the digital space maintained by the computing device. The user device can transmit the instructions to the computing device. For example, via Bluetooth or USB transfer. In some implementations, the user device can transmit, via the connection (e.g., Bluetooth or USB), the instructions to the computing device to manipulate display of the digital object of the digital space maintained by the computing device. The user device can communicate with the computing device via a TCP connection. In some implementations, the user device can transmit the retrieved instructions to the computing device. The user device can transfer the instructions in the form of machine executable code or text. To maintain the connection between transmissions of instructions, the user device can transmit a heartbeat at predetermined intervals to the computing device.

In another example, the user device can bypass the driver of the computing device and instead transmit instructions directly to the CAD package via the API. For example, the user device can transmit instructions containing keypresses directly to the CAD package via the API, such as via a command line interface or any other exposed API of the CAD package.

The user device can transmit to the computing device a single character of text to notify the computing device of an upcoming transmission of the instruction. For example, for instructions derived directly from keyboard inputs or indirectly from audio signals, the user device can transmit the instruction that includes the alphanumeric text, hotkey, or keyboard function. For example, if the user device received a selection of “7” on the keyboard, then the user device can transmit an instruction that includes the “7”.

The computing device can receive the instructions from the user device (STEP 416). In some implementations, computing device can receive, via the connection (e.g., Bluetooth or USB), the instructions to manipulate display of the digital object in the digital space maintained by the CAD package (e.g., application) of the computing device. In some implementations, the computing device can receive, from the user device, the instructions to manipulate display of the multi-dimensional model maintained by the CAD package of the computing device. The computing device can execute loops to check for information from the user device. For example, the computing device can receive instructions by executing the loop at a variable rate to check for new data from the user device. The computing device can execute the loop to constantly check for instructions from the user device. For example, the computing device can execute a while loop that waits for instructions to arrive for processing. The loop can depend on the connection status to the user device. For example, the loop can execute when the devices are connected, exit when the devices disconnect, and again execute when the devices reconnect. The computing device can process the information and send the same command whether communicating with a user device made utilizing Android (Google of Alphabet Inc. of Mountain View, Calif.) or Apple (Cupertino, Calif.) Operating System.

In another example, the CAD package of the computing device can receive instructions directly from the user device. For example, the CAD package can receive instructions containing keypresses directly from the user device and process the instructions via a command line interface or any other exposed API of the CAD package. In such examples, the CAD package can receive the instructions without the implementations described in steps 416-422.

The computing device can parse the instructions (STEP 418). The computing device can process the instructions. The computing device can parse the instructions and determine the appropriate command and associated factors. For example, the instruction parser 216 can identify that the instructions include keypresses “CTRL+ALT+Shift+F20”. The computing device can parse instructions received from user devices having various operating systems, such as iOS and Android. For example, the order of the numbers in the instructions can be device specific, so the computing device can extract specific numbers referenced for each specific action. The computing device can take the first letter of the instructions to identify that action. For example, the computing device can receive six degree of freedom manipulation information included in the instructions from the user device. In some implementations, the computing device can identify, from the instructions, a zoom identifier and scaling factor. In some implementations, the computing device can identify, from the instructions, a rotation identifier and coordinates on a screen of the user device. For example if the instructions include a letter of “r”, then the computing device can identify that the model is to be rotated. In some implementations, the computing device can identify, from the instructions, a pan identifier and a direction to pan in the digital space. For example if the instructions include a letter of “t”, then the computing device can identify that the model is to be translated or panned. In another example, the computing device can identify that the instructions include a request to re-center the model. In yet another example, the computing device can identify that the instructions include a request to call a hotkey. For example, if the user device transmitted an instruction that identifies a keyboard selection of “7”, then the computing device can receive the instruction that includes the “7”.

The computing device can process or parse instructions based on the audio signals. For example, the computing device can include a list of available hotkeys, keyboard functions, or keyboard shortcuts. The user device can include the processed audio inputs in the instructions provided to the computing device, which can compare the text the list. For example, the computing device can match the instructions including “zoom the model by a factor of 2” to a command to zoom the model by 2.

The computing device can generate a command from the instructions (STEP 420). In some implementations, the computing device can generate, based on the instructions, a command for manipulating a digital object in a digital space. For example, the computing device can generate the command to include the keypresses “CTRL+ALT+Shift+F20”. The computing device can generate the command to transmit to the CAD package via an API. For example, the computing device can include the parsed values in the command that is sent to the CAD package via the API. The API can be unique or designed for the CAD package. The computing device can download the API for CAD package. The API can include a list of functions that can be called to the CAD package. The computing device can generate the command based on the supported functions.

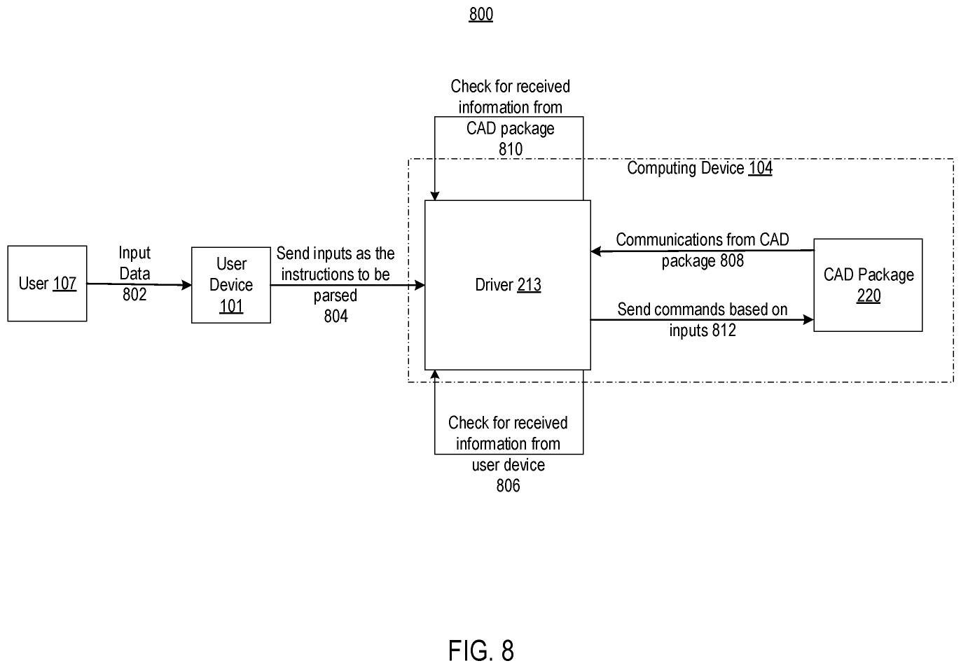

Referring now to FIG. 8 in conjunction with FIG. 4, FIG. 8 shows a flow diagram of an implementation of a method 800 for the user device to manipulate the multi-dimensional model maintained by the computing device. In particular, shown are data transmissions among the user device and the computing device. As discussed in reference to STEP 410, the user device can receive input data from the user (STEP 802). As discussed in reference to STEPS 412 and 414, the user device can send the inputs as the instructions to be parsed by the computing device (STEP 804). As discussed in reference to STEP 416, the driver of the computing device can check for received information from the user device (STEP 806).

The driver of the computing device can communicate with the CAD package to generate the command (STEP 808). The computing device can perform or generate calculations based on the instructions to generate the command. In some implementations, the computing device can identify, a center of rotation for the digital object in the digital space. For example, if the instructions include a rotation command, then the computing device can determine if a center of rotation needs to be calculated based on whether the model has been translated since the last rotation. The computing device can store a status (e.g., single Boolean) of whether the center of rotation needs to be recalculated.

The computing device can execute loops to check for information from the CAD package (STEP 810). The computing device can detect that the center needs to be recalculated based on a variety of events such as opening a new document in the CAD package. In another example, if the computing device generates a command that triggers the status (e.g., translation command), then the computing device can change the status (e.g., set to true) to indicate that a new center of rotation needs to be recalculated. If the model has not been translated, then the computing device can retrieve a stored center of rotation.

If a new center of rotation needs to be calculated for a 3D body (because the model has been translated), then the computing device can return the screen pixels representing the corners of the visible CAD display. The computing device can obtain points corresponding to the screen pixels by calling a command via the API to the CAD package. For example, the computing device can obtain points that are half way on x and y axis and provide the midpoints of the visible display. An example of SolidWorks API is System.object GetVisibleBox( ). The computing device can assign a 3-dimensional point at the center of this rectangle (e.g., view of the digital space on the screen) with a Z value of 0 (assuming X, Y to represent the center value). In some implementations, the computing device can generate, a second point having three dimensional coordinates, the second point forming a vector that is normal to a z-axis of the digital space displayed on the screen of the computing device. The computing device can assign a second value with Z=1 to create a series of points that if combined into a ray would be normal to the screen. The computing device can store the values in memory or local storage.

The computing device can translate the two points from pixel coordinates on the screen into model coordinates in the CAD package through a direct function via the API. In some implementations, the computing device can generate coordinates of the digital space based on the coordinates on the screen of the user device. The computing device can execute a function to convert the screen coordinates into model coordinates in the CAD package. The computing device can create a ray in model coordinates from these two newly assigned model coordinate points. In some implementations, the computing device can assign, based on the first point and the second point, one or more bounding boxes to the digital object in the digital space. For each discrete 3D body on the screen, the computing device can assign a bounding box provided by the CAD package as AABB coordinates in 3 Dimensions. For example, to assign the bounding box, the computing device can make an API call of an axis aligned bounding box. In some implementations, the computing device can identify pixel identifiers at each corner of the digital space displayed on a screen of the computing device. To define an axis aligned bounding box, the computing device can take two points from the xyz min and xyz max to define the six planed prism. In some implementations, the computing device can identify, based on the pixel identifiers, a first point having three dimensional coordinates at a center of the digital space. These two 3-dimensional model points represent the corners of the bounding box in 3-dimensional space.

The computing device can filter the bounding boxes based on intersections with the ray into the screen. In some implementations, the computing device can identify, one or more intersections between the one or more bounding boxes and the vector. The computing device can include the bounding boxes with an intersection. In some implementations, the computing device can identify, based on the one or more intersections, the center of rotation for the digital object in the digital space. The computing device can return the nearest intersection point of these bounding boxes to the surface of the screen as the center of rotation for the model. In some implementations, the computing device can generate, based on the coordinates on the screen of the user device and the center of rotation, the command comprising a rotation request for rotating the digital object in the digital space. Once the computing device calculates or identifies the center of rotation, the computing device can provide the coordinates for center of rotation (x, y, and z) as well as degrees of rotation (x and y) to the CAD package via the API. In some implementations, the computing device can generate, based on the instructions, the command comprising a rotation request and the coordinates of the digital space. The computing device can rotate the model about that point by the amount supplied in the instructions from the user device. The computing device can store the center of rotation for future use.

If computing device fails to find a center of rotation, then the computing device can use the center of mass of the body in the CAD package. The computing device can call or retrieve the center of mass from the CAD package via the API. The computing device can call or retrieve the degrees of rotation (x and y) in the CAD package through a direct command referenced from the API of the CAD package. The computing device can generate a command to rotate the model based on the coordinates. As will be discussed in reference to STEP 422, the driver of the computing device can send the commands to the CAD package (STEP 812).

The computing device can generate a command from the instructions to zoom the model. In some implementations, the computing device can generate, based on the instructions, the command comprising a zoom request and the scaling factor for zooming in the digital space. If the user device transmits an instruction that includes a request to zoom the model, then the computing device can receive the instruction and parse out or identify the zoom request and the associated scaling factor (and create a scaling factor from that value). For example, the computing device can identify the zoom distance in the instruction.

The computing device can generate a command from the instructions to pan the model. In some implementations, the computing device can generate, based on the instructions, the command comprising a pan request and the direction to pan in the digital space. If the user device transmits an instruction that includes a pan command along with the coordinates of translation, then the computing device can receive the instruction and parse out or identify the pan request and the x and y coordinates for translation. The computing device can generate a command to pan the model based on the x and y coordinates for translation. The computing device can obtain the amounts that are provided in the instructions from the user device, and generate a command to pan the model by that amount (multiplied by scaling factor). The 6 degree of freedom commands generated by the computing device can be relative to where the model is in space. For example, the command does not indicate the model to move to a specific 3D location but indicates how much the model is to move.

The computing device can generate a command from the instructions based on keypresses. For example, if the user device received a selection of “7” on its keyboard, then the computing device can generate a command that includes a keypress of “7” to mimic the typing of the command on the keyboard of the computing device.

The computing device can provide the command to a CAD package to manipulate the model (STEP 422). The computing device can provide the command to the CAD package via the API. The computing device can provide the command for the specific manipulation of the model. The computing device can communicate directly with the CAD package via the API or by providing commands that mirror the keyboard inputs from the user device. For example, the computing device can provide a specific keyboard text command through the user interface such as CTRL+ALT+Shift+F20. In another example, if the user device received a selection of “7” on its keyboard, then the computing device can transmit a command that includes a keypress of “7” as though as the command was typed on the keyboard of the computing device.

The computing device can provide the commands with hotkeys to the CAD package via the API. For example, the hotkeys can include a function to re-center the model. In another example, the hotkeys can include custom Macros made by the user or customized for the CAD package. The computing device can call these commands as hotkeys via either the keyboard input or the API function to re-center the model. If the command is to pan the model, the computing device can call the API function for translation and include the x and y coordinates based on the parsed instruction received from the user device. If the command is to zoom the model, the computing device can call the API function to zoom the model based on the scaling factor included in the command. If the command is to rotate the model, the computing device can call the API function to rotate the model based on the coordinates included in the command.

The computing device can provide the commands to the CAD package while the CAD package receives other inputs, such as from a keyboard or computer mouse of the computing device. Because the computing device provides the commands to the CAD package via the API, the commands (e.g., six degrees of freedom manipulations) will not override the computer mouse or keyboard inputs. The CAD package can use the commands in tangent with the computer mouse or keyboard inputs. The CAD package can process the commands and other inputs simultaneously.

If the computing device provides a command corresponding to a hotkey selected on the user device, the predetermined keyboard shortcut can be translated by the computing device to a virtual keyboard input and provided to the CAD package as a virtual keyboard input. This the computing device can perform this translation through functionality within the computing device that mimics a keyboard input.

The computing device of the application can verify that the CAD package is in an open or active window capable of receiving the command before providing the command. Through a command listed in the API of the CAD package, the computing device can verify to ensure that the CAD package has an open window on the computing device. For example, the computing device can call an operating system function to identify the active window. If the active window corresponds to the CAD package, then the computing device can provide the command via the operating system library. By verifying the presence of the open window, the computing device can ensure that if a command corresponding to a hotkey is provided, then the CAD package can receive and execute the command. If there was no open window, then the command, in effect, would be blocked.

For commands derived from the keyboard inputs, the driver of the computing device can send the text from the keyboard with the CAD package similarly to how the hotkeys and enter command are sent. The driver of the computing device can provide the virtual keyboard inputs after confirming that the CAD package has the window opened.

While various implementations of the methods and systems have been described, these implementations are illustrative and in no way limit the scope of the described methods or systems. Those having skill in the relevant art can effect changes to form and details of the described methods and systems without departing from the broadest scope of the described method and systems. Thus, the scope of the methods and systems described herein should not be limited by any of the illustrative implementations and should be defined in accordance with the accompanying claims and their equivalents.

What is claimed is:

1. A method for a user device to manipulate a multi-dimensional model maintained by a computing device, the method comprising:
displaying, by one or more processors of the user device, on a screen of the user device, a manipulation area for controlling display of the multi-dimensional model maintained by the computing device;
receiving, by the one or more processors, from a gesture handler of the user device, an identification of an input received by the screen of the user device;
generating, by the one or more processors, based on the identification, an instruction for manipulating a digital object in a digital space; and
transmitting, by the one or more processors, the instruction to a driver of the computing device to manipulate display of the digital object in the digital space maintained by the computing device.

2. The method of claim 1, wherein generating the instruction comprises generating, by the one or more processors, based on the identification, the instruction comprising a rotation identifier and coordinates for rotating the digital object in the digital space.

3. The method of claim 1, wherein generating the instruction comprises generating, by the one or more processors, based on the identification, the instruction comprising a rotation identifier and coordinates for rotating the digital space.

4. The method of claim 1, wherein generating the instruction comprises generating, by the one or more processors, based on the identification, the instruction comprising a zoom identifier and a scaling factor for zooming in the digital space.

5. The method of claim 1, wherein the identification is a first identification, the input is a first input, and wherein generating the instruction comprises:
receiving, by the one or more processors, from the gesture handler of the user device, a second identification of a second input received by the user device; and
generating, by the one or more processors, based on receiving the first identification and the second identification within a predetermined amount of time, the instruction for manipulating the digital object in the digital space.

6. The method of claim 1, wherein generating the instruction comprises generating, by the one or more processors, based on the identification, the instruction comprising a pan identifier and a direction to pan in the digital space.

7. The method of claim 1, further comprising:
maintaining, by the one or more processors, a predetermined instruction for manipulating the digital object in the digital space;
displaying, on the screen of the user device, a button corresponding to the predetermined instruction;
receiving, by the one or more processors, from the gesture handler of the user device, a selection of the button on the user device; and
transmitting, by the one or more processors, the predetermined instruction to the driver of the computing device to manipulate display of the digital object in the digital space maintained by the computing device.

8. The method of claim 7, further comprising:
displaying, by the one or more processors, on the screen of the user device, a request to configure the button;
receiving, by the one or more processors, subsequent to the request, alphanumeric input corresponding to the button; and
updating, by the one or more processors, based on the alphanumeric input, the predetermined instruction associated with the button for manipulating the digital object in the digital space.

9. The method of claim 1, wherein receiving the identification of the input comprises receiving, by the one or more processors, from an audio handler of the user device, the identification of the input received by a microphone of the user device.

10. The method of claim 9, wherein generating the instruction comprises:
identifying, by the one or more processors, a predetermined instruction corresponding to the identification; and
generating, by the one or more processors, based on the predetermined instruction, the instruction for manipulating the digital object in the digital space.

11. The method of claim 1, wherein transmitting the instruction comprises:
transmitting, by the one or more processors, a request to the computing device to connect with the computing device via Bluetooth or USB;
receiving, by the one or more processors, a response from the computing device to establish a connection with the computing device via Bluetooth or USB; and
transmitting, by the one or more processors, via the connection, the instruction to the driver of the computing device to manipulate display of the digital object of the digital space maintained by the computing device.

12. The method of claim 1, further comprising:
receiving, by the one or more processors, from the computing device, a request for alphanumeric input; and
displaying, by the one or more processors, a keyboard responsive to the request.

13. A method for a computing device to enable a user device to manipulate a multi-dimensional model maintained by an application of the computing device, the method comprising:
receiving, by one or more processors of the computing device, from the user device, an instruction to manipulate display of the multi-dimensional model maintained by the application of the computing device;
generating, by the one or more processors, based on the instruction, a command for manipulating a digital object in a digital space; and
providing, by the one or more processors, the command to the application to manipulate the digital object in the digital space.

14. The method of claim 13, wherein generating the command comprises:
identifying, by the one or more processors, from the instruction, a rotation identifier and coordinates on a screen of the user device;
identifying, by the one or more processors, a center of rotation for the digital object in the digital space; and
generating, by the one or more processors, based on the coordinates on the screen of the user device and the center of rotation, the command comprising a rotation request for rotating the digital object in the digital space.

15. The method of claim 14, wherein identifying the center of rotation comprises:
identifying, by the one or more processors, pixel identifiers at each corner of the digital space displayed on a screen of the computing device;
identifying, by the one or more processors, based on the pixel identifiers, a first point having three dimensional coordinates at a center of the digital space;
generating, by the one or more processors, a second point having three dimensional coordinates, the second point forming a vector that is normal to a z-axis of the digital space displayed on the screen of the computing device;
assigning, by the one or more processors, based on the first point and the second point, one or more bounding boxes to the digital object in the digital space;
identifying, by the one or more processors, one or more intersections between the one or more bounding boxes and the vector; and
identifying, by the one or more processors, based on the one or more intersections, the center of rotation for the digital object in the digital space.

16. The method of claim 13, wherein generating the command comprises:
identifying, by the one or more processors, from the instruction, a rotation identifier and coordinates on a screen of the user device;
generating, by the one or more processors, coordinates of the digital space based on the coordinates on the screen of the user device; and
generating, by the one or more processors, based on the instruction, the command comprising a rotation request and the coordinates of the digital space.

17. The method of claim 13, wherein generating the command comprises:
identifying, by the one or more processors, from the instruction, a zoom identifier and scaling factor
generating, by the one or more processors, based on the instruction, the command comprising a zoom request and the scaling factor for zooming in the digital space.

18. The method of claim 13, wherein generating the command comprises:
identifying, by the one or more processors, from the instruction, a pan identifier and a direction to pan in the digital space; and
generating, by the one or more processors, based on the instruction, the command comprising a pan request and the direction to pan in the digital space.

19. The method of claim 13, wherein receiving the instruction comprises receiving, by the one or more processors, a request to from the user device to connect via Bluetooth or USB;
transmitting, by the one or more processors, a response to the user device to establish a connection with the user device via Bluetooth or USB; and
receiving, by the one or more processors, via the connection, the instruction to manipulate display of the digital object in the digital space maintained by the application of the computing device.

20. The method of claim 13, further comprising:
identifying, by the one or more processors, a request by the application for alphanumeric input; and
transmitting, by the one or more processors, the request to the user device for the alphanumeric input.
